(19) United States
(12) Patent Application Publication
(10) Pub. No.: US 2012/0268870 A1
(43) Pub. Date: Oct. 25, 2012

(54) ELECTRONIC DEVICE AND METHOD FOR MANUFACTURING ELECTRONIC DEVICE

(75) Inventor: Masaki Ishikawa, Yokohama (JP)

(73) Assignee: FUJITSU LIMITED, Kawasaki-shi (JP)

(21) Appl. No.: 13/444,514

(22) Filed: Apr. 11, 2012

(30) Foreign Application Priority Data
Apr. 25, 2011 (JP) 2011-097526

(51) Int. Cl. H05K 5/00; B23P 11/00

(52) U.S. Cl. 361/679.01; 29/729

(57) ABSTRACT

An electronic device includes a device unit including a rotation mechanism, a bracket on which the device unit is mounted, a chassis including an arrangement area onto which the bracket is installed, plural vibration absorbing members provided in the arrangement area, and first and second support panels having the arrangement area provided therebetween. A first engagement mechanism is provided between the first support panel and the bracket, and a second engagement mechanism is provided between the second support panel. The first and the second engagement mechanisms are configured to engage the chassis and the bracket by compressing the plural vibration absorbing members between the chassis and the bracket.

### CROSS-REFERENCE TO RELATED APPLICATIONS

This application is based upon and claims the benefit of priority of the prior Japanese Patent Application No. 2011-097526 filed on Apr. 25, 2011, the entire contents of which are incorporated herein by reference.

### FIELD

The embodiments discussed herein are related to an electronic device including a device unit having a rotation mechanism (e.g., hard disk drive (HDD) unit) and a method for manufacturing the electronic device.

### BACKGROUND

In a case where a hard disk drive (HDD) of a device unit (e.g., HDD unit) of a personal computer is driven, the rotational vibration generated by the HDD unit is known to be the cause of, for example, noise or housing resonance.

As a countermeasure against the vibration of the HDD unit, Japanese Laid-Open Patent Publication No. 2006-164330 teaches a sheet-like vibration attenuating cushion provided between a mechanical chassis and a HDD bracket or a drive bracket.

A thin-plate-worked metal chassis is used by a device including a rotation mechanism (e.g., electronic device including a HDD unit) for grounding the HDD unit and maintaining mechanical strength of the HDD unit.

Such metal chassis has a fixing part provided at a lower side of the HDD unit. With the configuration where the fixing part is provided in the vicinity of a disk rotation part of the HDD unit, a slight displacement of the fixing part may create a subtle space between the HDD unit and the metal chassis. The presence of the space may cause resonance (chattering vibration) at the space and create a discomforting noise when the HDD unit is driven. The resonant vibration may also be caused by a space resulting from secular change.

In a case where the fixing part is provided on a lower side of the HDD unit, it is difficult to perform a fixing task due to the fixing part being hidden by the HDD unit. Therefore, it is difficult to ensure a sufficient fixed state.

### SUMMARY

According to an aspect of the invention, there is provided an electronic device including: a device unit including a rotation mechanism; a bracket on which the device unit is mounted; a chassis including an arrangement area to which the bracket is installed, plural vibration absorbing members provided in the arrangement area, and first and second support panels having the arrangement area provided therebetween; a first engagement mechanism provided between the first support panel and the bracket; and a second engagement mechanism provided between the second support panel and the bracket; wherein the first and the second engagement mechanisms are configured to engage the chassis and the bracket by compressing the plural vibration absorbing members between the chassis and the bracket.

The object and advantages of the invention will be realized and attained by means of the elements and combinations particularly pointed out in the claims.

It is to be understood that both the foregoing generation description and the followed detailed description are exemplary and explanatory and are not restrictive of the invention, as claimed.

### BRIEF DESCRIPTION OF DRAWINGS

FIG. 1 is a schematic diagram illustrating a portion of an electronic device according to a first embodiment of the present invention;

FIG. 2 is a flowchart illustrating procedures for assembling an electronic device according to an embodiment of the present invention;

FIG. 3 is a cross-sectional view illustrating a procedure of fixing a bracket to a chassis according to an embodiment of the present invention;

FIG. 4 is a schematic diagram illustrating a sandwich structure constituted by a bracket, a chassis, and a gasket (prior to compression) according to an embodiment of the present invention;

FIG. 5 is a front view of a PC according to a second embodiment of the present invention;

FIG. 6 is a rear view of a PC according to an embodiment of the present invention;

FIG. 7 is a rear perspective view of a rear surface cover according to an embodiment of the present invention;

FIG. 8 is a perspective view illustrating a rear stand in a state being detached from a chassis according to an embodiment of the present invention;

FIG. 9 is a rear perspective view illustrating a PC in a state where a rear surface cover and a stand support part are detached therefrom according to an embodiment of the present invention;

FIG. 10 is a rear view illustrating a PC in a state where a rear surface cover and a stand support part are detached therefrom according to an embodiment of the present invention;

FIG. 11 is a schematic diagram illustrating an example of a configuration of an HDD unit according to an embodiment of the present invention;

FIG. 12 is a perspective view illustrating an example of a HDD unit and a bracket according to an embodiment of the present invention;

FIG. 13 is a rear perspective view of a part of a PC in a state where a rear surface cover, a stand support part, a HDD unit, and a bracket are detached therefrom according to an embodiment of the present invention;

FIG. 14 is a perspective view of one of the support panels when viewed from an arrangement area according to an embodiment of the present invention;

FIG. 15 is a perspective view of one of the support panels when viewed from the outside of an arrangement area according to an embodiment of the present invention;

FIG. 16 is a perspective view illustrating a PC viewed from the rear in a state where support panels are mounted on a chassis according to an embodiment of the present invention;

FIG. 17 is a rear view of a PC in a state where support panels are mounted on a chassis according to an embodiment of the present invention;

FIG. 18 is an exploded view of an engagement mechanism according to an embodiment of the present invention;

FIG. 19A is a schematic diagram illustrating an engagement mechanism before a bracket and support panels are engaged according to an embodiment of the present invention;

FIG. 19B is a schematic diagram illustrating an engagement mechanism after a bracket and support panels are engaged according to an embodiment of the present invention;

FIG. 20A is a schematic diagram illustrating an example of a locking mechanism according to an embodiment of the present invention;

FIG. 20B is a schematic diagram illustrating an example of a gasket according to an embodiment of the present invention;

FIG. 21A is a schematic diagram illustrating a locking mechanism before a bracket and a chassis are engaged according to an embodiment of the present invention;

FIG. 21B is a schematic diagram illustrating a locking mechanism after a bracket and a chassis are engaged according to an embodiment of the present invention;

FIG. 22 is a schematic diagram illustrating a state before a bracket and support panels are engaged according to an embodiment of the present invention;

FIG. 23 is a schematic diagram illustrating a state after a bracket 6 and support panels are engaged (i.e. engaged state) according to an embodiment of the present invention;

FIG. 24 is a cross-sectional view of the engaged state taken along line XXIV-XXIV of FIG. 23;

FIG. 25 is a schematic diagram illustrating a positional relationship of a rotation mechanism of a HDD unit, engagement mechanisms, and locking mechanisms according to an embodiment of the present invention;

FIG. 26 is a cross-sectional view illustrating a housing structure having a stand chassis attached to support panels according to an embodiment of the present invention;

FIG. 27 is a flowchart illustrating procedures for assembling a PC according to an embodiment of the present invention;

FIG. 28 is a cross-sectional view illustrating a modified example of an engagement mechanism according to an embodiment of the present invention;

FIG. 29 is a perspective view illustrating a modified example of an engagement mechanism according to an embodiment of the present invention;

FIG. 30 is a perspective view illustrating a modified example of a locking mechanism according to an embodiment of the present invention; and

FIG. 31 is a schematic diagram illustrating a modified example of a bracket having gaskets mounted thereon according to an embodiment of the present invention.

### DESCRIPTION OF EMBODIMENTS

### First Embodiment

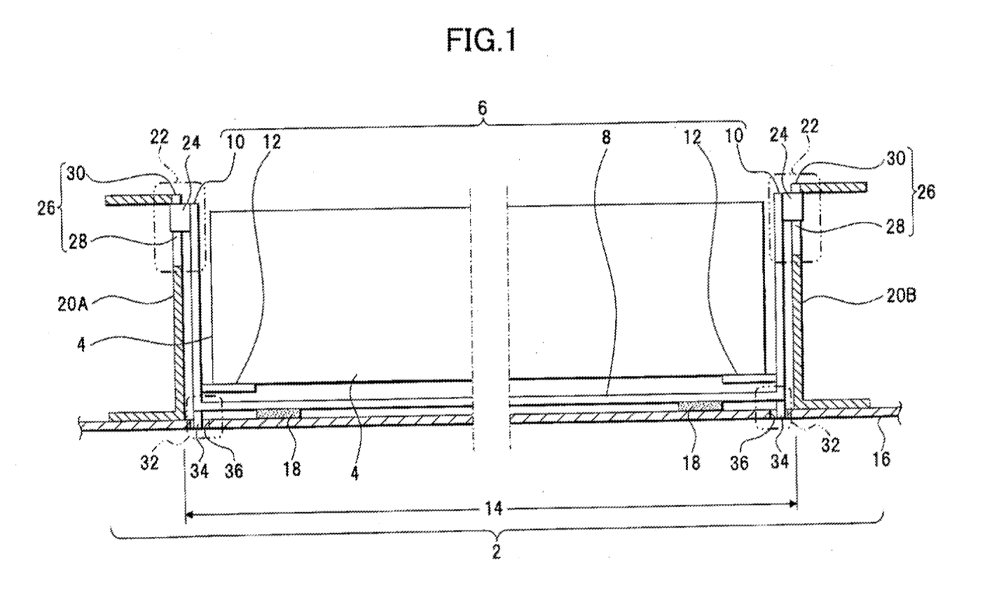

An electronic device 2 according to a first embodiment of the present invention is described with reference to FIG. 1. FIG. 1 is a schematic diagram illustrating a portion of the electronic device 2 according to the first embodiment of the present invention. It is to be noted that the configuration of the electronic device 2 illustrated in FIG. 1 is merely an example and is not limited to the configuration illustrated in FIG. 1.

The electronic device 2 illustrated in FIG. 1 is one example of the electronic device of the present invention. The electronic device 2 includes a HDD unit 4. The HDD unit 4 is an example of a device unit having a rotation mechanism. The device unit is not to be limited to the HDD unit. The device unit may be another type of unit as long as the unit has a rotation mechanism that generates vibration when the rotation mechanism is driven.

The electronic device 2 includes a fixing frame member for fixing the HDD unit 4. A unit bracket (hereinafter also simply referred to as “bracket”) 6 is used as the fixing frame member. The bracket 6 has a frame body that fixes the HDD unit 4. Because the HDD unit 4 has a flat rectangular parallelepiped shape, the bracket 6 has a rectangular bottom plate 8, a pair of side plates 10 that are formed upright in a perpendicular direction with respect to a long side of the bottom plate 8, and plural shelf parts 12 provided between the side plates 10 in a manner protruding from one side plate 10 toward the other side plate 10 on the opposite side. The HDD unit 4 is mounted on the shelf parts 12. Each side plate 10, which has a greater height than that of a sidewall of the HDD unit 4, serves as a protection member of the HDD unit 4.

A chassis 16 includes an arrangement area 14. The bracket 6 is to be arranged inside the arrangement area 14. Accordingly, the arrangement area 14 has a shape and an area that can encompass the bottom plane of the bracket 6. The chassis 16 may be, for example, a thin-plate-worked metal plate having high rigidity and satisfactory conductivity. Plural gaskets 18 are also arranged in the arrangement area 14. For example, each of the plural gaskets 18 may be a buffering pad formed of a vibration absorbing material. The gaskets 18 may be placed in plural areas in the horizontal (width) and longitudinal directions of the bracket 6. Each gasket 18 is interposed between the bracket 6 and the chassis 16. That is, the gaskets 18, the bracket 6, and the chassis 16 constitute a vibration controlling configuration including a sandwich structure having the gaskets 18 provided between the bracket 6 and the chassis 16.

The chassis 16 may include or be attached with a pair of support panels 20A, 20B having the arrangement area 14 provided between the support panels 20A, 20B. That is, each of the support panels 20A, 20B may be a part of the chassis 16 or a component separate from the chassis 16. In a case where the support panels 20A, 20B are components separate from the chassis 16, the support panels 20A, 20B may be integrated with the chassis 16 by fixing the support panels 20A, 20B to the chassis 16 with a fixing member (e.g., fixing bolt, rivet). Each of the support panels 20A, 20B has a panel surface that is parallel to the corresponding side plate 10 of the bracket 6.

Plural engagement mechanisms 22 are provided between each of the support panels 20A, 20B and the corresponding side plate 10 of the bracket 6 for engaging the support panels 20A, 20B and the corresponding side plates 10. The plural engagement mechanisms 22 are positioned in a manner having the arrangement area 14 provided therebetween. The engagement mechanism 22 includes, for example, a protrusion part 24 and an engagement part 26. In this embodiment, the protrusion part 24 is provided in each of the side plates 10, and the engagement part 26 is provided in each of the support panels 20A, 20B. The engagement part 26 includes a window part 28 into which the protrusion part 24 is inserted and a lock part 30 to which the protrusion part 24 is locked. FIG. 1 illustrates the protrusion part 24 and the engagement part 26 contacting each other. That is, FIG. 1 illustrates an engaged state of the protrusion part 24 and the engagement part 26.

Further, plural locking mechanisms 32 are provided between the chassis 16 and the bottom plate 8 of the bracket 6 for locking the chassis 16 and the bracket 6 together. The plural locking mechanisms 32 are positioned in the arrangement area 14. The locking mechanism 32 includes, for example, a protrusion part 34 and a recess part (e.g., slit) 36. In this embodiment, the protrusion part 34 is provided in the bracket 6, and the slit 36 is provided in the chassis 16. Before or after the engaged state of the engagement mechanism 22 is established, the protrusion part 34 is inserted into the slit 36. By inserting the protrusion part 34 into the slit 36, the bracket 6 can be fixed at a predetermined position in the arrangement area 14. Thus, the bracket 6 can be prevented from moving beyond the arrangement area 14. FIG. 1 illustrates an engaged state of the protrusion part 34 and the slit 36 of the locking mechanism 32.

With the above-described configuration, the bracket 6 can be placed on the plural gaskets 18 in the arrangement area 14 in a well-balanced manner. Further, the gaskets 18 are maintained in a compressed state between the bottom plate 8 of the bracket 6 and the chassis 16. In this state, the protrusion parts 24 of the bracket 6 are engaged with the engagement parts 26 of the corresponding support panels 20A, 20B. Thereby, the bracket 6 is fixed at a predetermined position by engaging each of the support panels 20A, 20B. Additionally, the recovering force of the compressed gaskets 18 forces the protrusion parts 24 and the engagement parts 26 to further engage each other. As a result, the bracket 6 can be firmly fixed between the support panels 20A and 20B owing to the engagement by the engagement mechanisms 22 and the increased engagement by the recovering force of the gaskets 18.

Further, the bracket 6 being in an engaged state between the support panels 20, 20B is locked to the chassis 16 within the arrangement area 14 by the locking mechanisms 32. Therefore, the bracket 6 can be firmly locked to the chassis 16 within the arrangement area 14 owing to the locking force of the locking mechanism 32 in addition to the engagement by the engagement mechanisms 22, the recovering force of the gaskets 18, and a friction force between the gaskets 18 and the bottom plate 8 of the bracket 6.

With the above-described configuration, a sandwich structure (vibration control configuration) constituted by the bracket 6, the gaskets 18, and the chassis 16 can be obtained. Thus, the engaging strength of the engagement mechanisms 22 can be increased by the recovering force of the compressed gaskets 18 generated between the bracket 6 and the chassis 16.

Accordingly, no space is formed between the bracket 6 and the chassis 16 to which the HDD unit 4 is fixed. Further, the generation of a space resulting from secular change can be prevented.

Therefore, the vibration generated by the rotation of the HDD unit 4 can be absorbed by the gaskets 18. Thus, resonance due to the space or noise due to chattering vibration can be prevented.

Although the electronic device 2 of this embodiment is described having a configuration including the locking mechanisms 32, the electronic device 2 may be configured without the locking mechanisms 32.

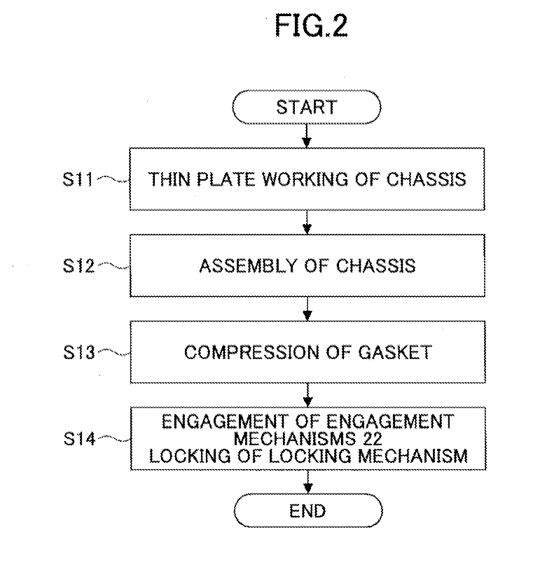

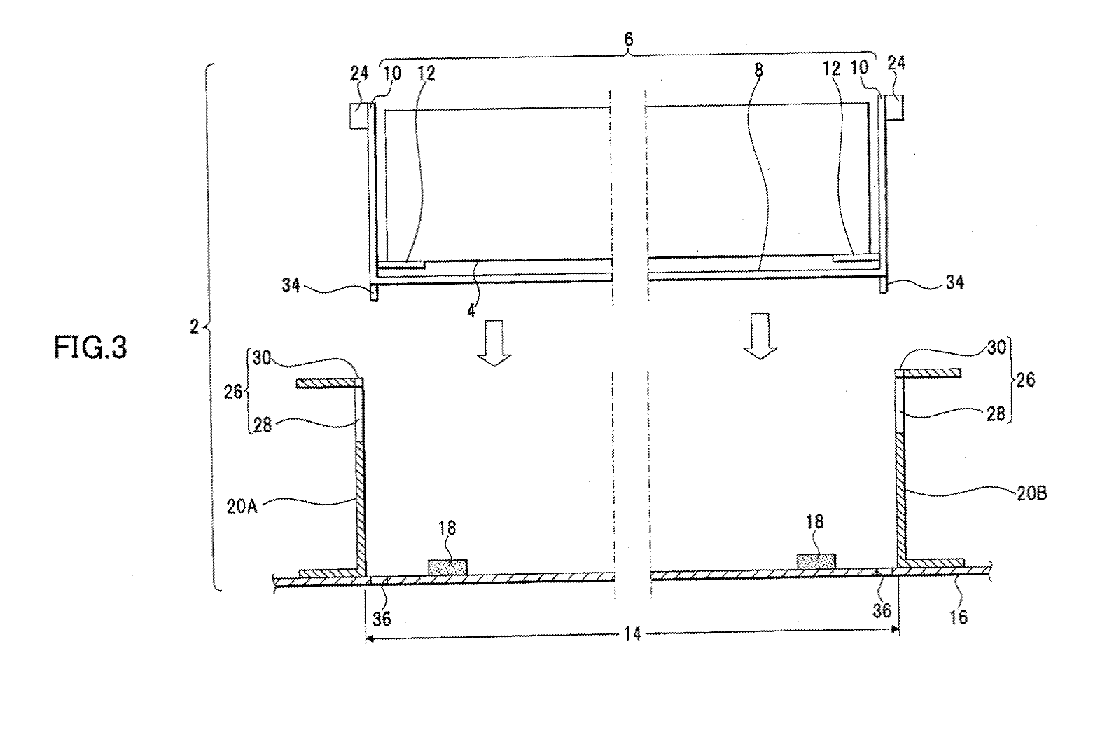

Next, a method for manufacturing the electronic device 2 according to an embodiment of the present invention is described with reference to FIGS. 2 and 3. FIGS. 2 and 3 are drawings for describing an example of a method for manufacturing the electronic device 2.

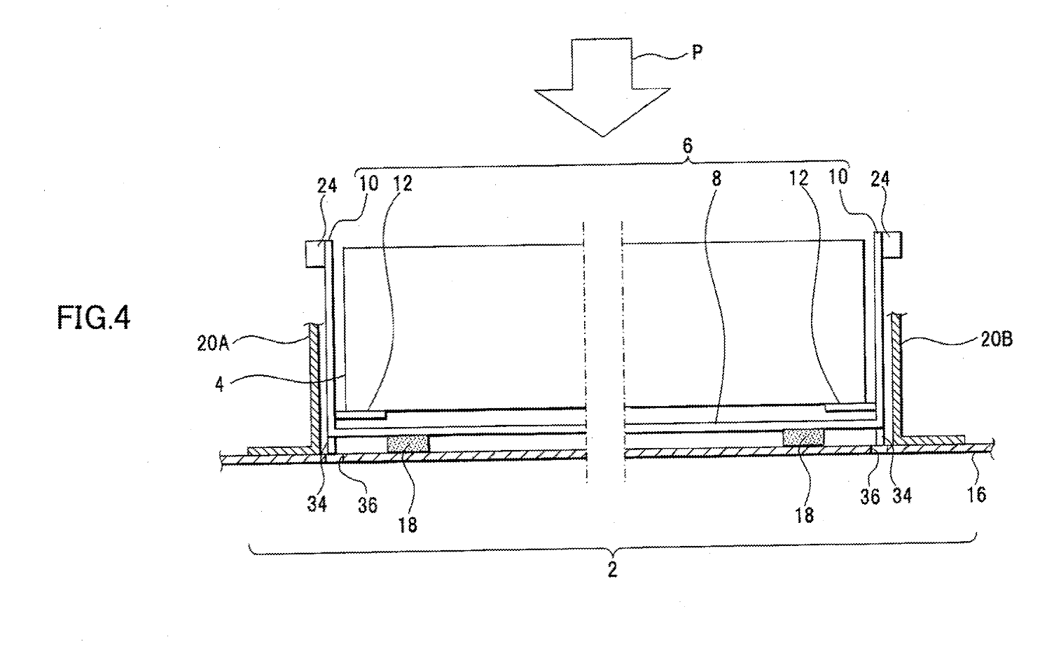

FIG. 2 is a flowchart illustrating the procedures for assembling the electronic device 2 according to an embodiment of the present invention. FIG. 3 is a cross-sectional view illustrating a procedure of fixing the bracket 6 to the chassis 16 according to an embodiment of the present invention. FIG. 4 is a schematic diagram illustrating a sandwich structure constituted by a bracket, a chassis, and a gasket (prior to compression) according to an embodiment of the present invention. Prior to being assembled, the chassis 16 is formed by thin-plate-working (Step S11). By the thin-plate-working process, the slit 36 of the locking mechanism 32 is formed in the arrangement area 14.

Then, assembly of the chassis 16 is performed (Step S12). In the assembly, plural of the gaskets 18 are arranged in the arrangement area 14 of the chassis 16. Further, the support panels 20A, 20B are erected on the chassis 16 in a manner having the arrangement area 14 provided between the support panels 20A, 20B. In a case where the support panels 20A, 20B form a united body (integrated body) with the chassis 16, the support panels 20A, 20B are formed together with the chassis 16 by thin-plate-working in Step S11. In a case where the support panels 20A, 20B do not form a united body (integrated body) but are components separate from the chassis 16, the support panels 20A, 20B may be attached to the chassis 16, for example, by using fixing screws or rivets or by welding.

In order to fix the bracket 6 having the HDD unit 4 mounted thereon to the chassis 16, the bracket 6 is placed on a top surface of the gaskets 18 arranged in the arrangement area 14 of the chassis 16 and pressed against the gaskets 18, so that the gaskets 18 are compressed (Step S13). In fixing the bracket 6 to the chassis 16, the bracket 6 is arranged on top of the gaskets 18 provided in the arrangement area 14 of the chassis 16 as illustrated in FIG. 3. By applying pressure to the bracket 6 arranged on the gaskets 18 in the arrow P direction illustrated in FIG. 4, the gaskets 18 are compressed between the chassis 16 and the bottom plate 8 of the bracket 6.

While maintaining this compressed state with the bracket 6, the bracket 6 and the support panels 20A, 20B are engaged with the engagement mechanisms 22 and the gaskets 18 are locked to the chassis 16 with the locking mechanisms 32 (Step S14). Thereby, the bracket 6 having the HDD unit 4 mounted thereon can be fixed to the chassis 16, and the HDD unit 4 can be arranged in the arrangement area 14 as illustrated in FIG. 1.

It is to be noted that the process of locking with the locking mechanisms 32 may be omitted from assembly procedures in an embodiment where the electronic device 2 does not include the locking mechanisms 32.

### Second Embodiment

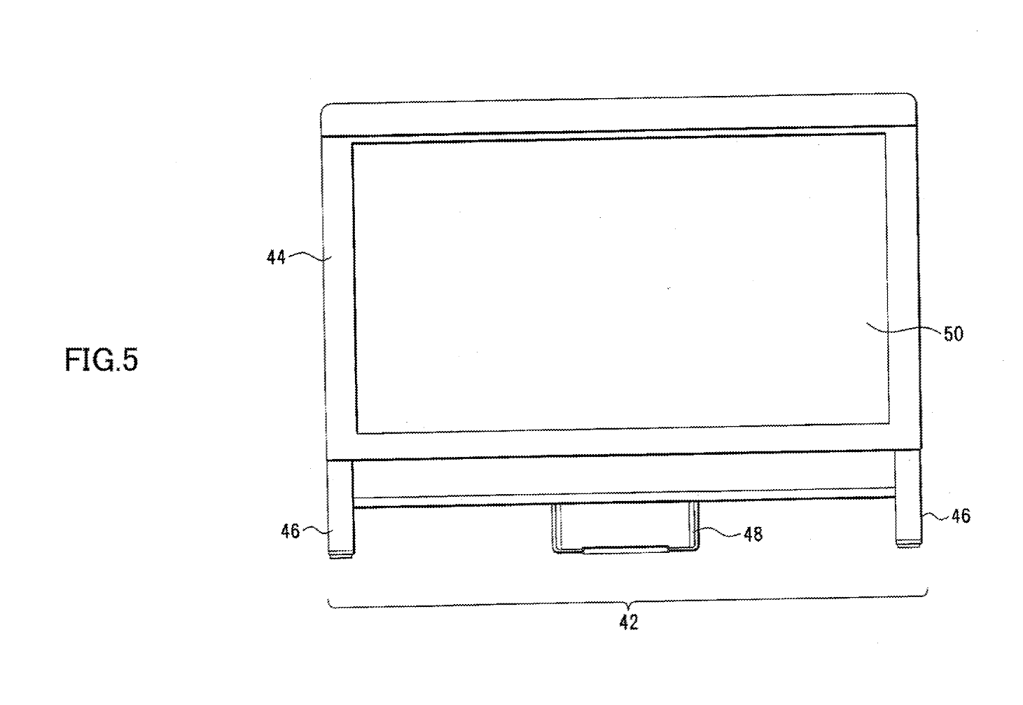

Next, a personal computer (PC) 42 according to a second embodiment of the present invention is described with reference to FIG. 5.

FIG. 5 is a front view of the PC 42 according to the second embodiment of the present invention. It is to be noted that the configuration of the PC 42 illustrated in FIG. 5 is merely an example and is not limited to the configuration illustrated in FIG. 5. In the second embodiment, like components are denoted with like reference numerals as those of the first embodiment and are not further described.

The PC 42 illustrated in FIG. 5 is one example of the electronic device of the present invention. The PC 42 includes a housing 44, a pair of front stands 46, and a rear stand 48. The housing 44 includes a display part 50 for displaying an image(s) on a screen. The front stands 46 are provided one on each side part (left/right side parts) of the housing 44. The rear stand 48 is provided on a rear side of the housing 44. The rear stand 46 is formed having a larger support bearing surface than that of the front stand 46. Accordingly, the housing 44 is stably supported and held erect at three points, that is, the pair of the front stands 46 and the rear stand 48. The display part 50 of the housing 44 can be adjusted from an upright position to an inclined position by adjusting the angle of the rear stand 48.

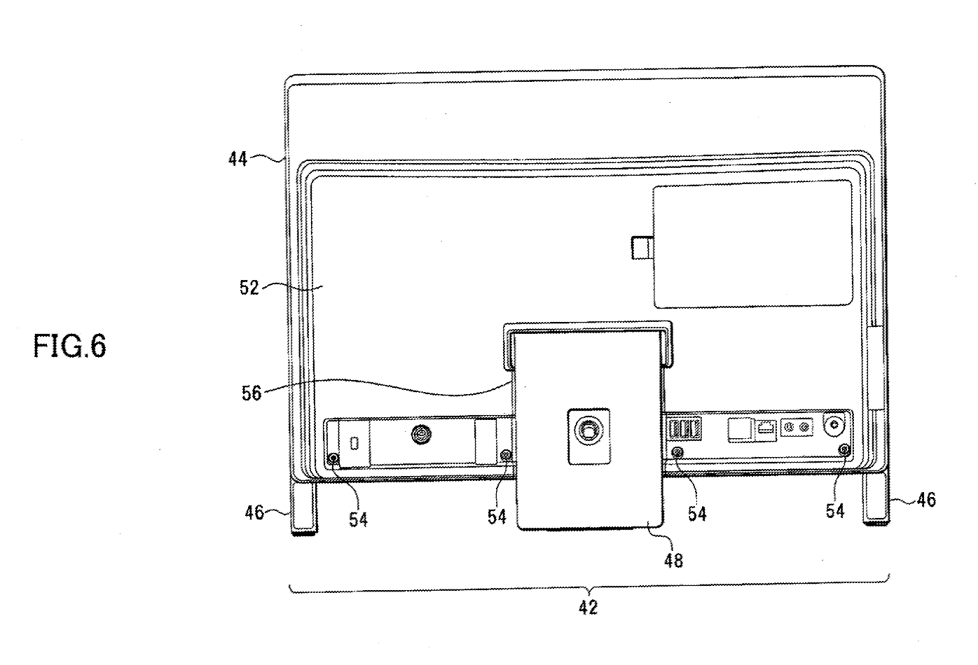

Next, a rear side of the PC 42 according to an embodiment of the present invention is described with reference to FIG. 6. FIG. 6 is a rear view of the PC 42 according to an embodiment of the present invention.

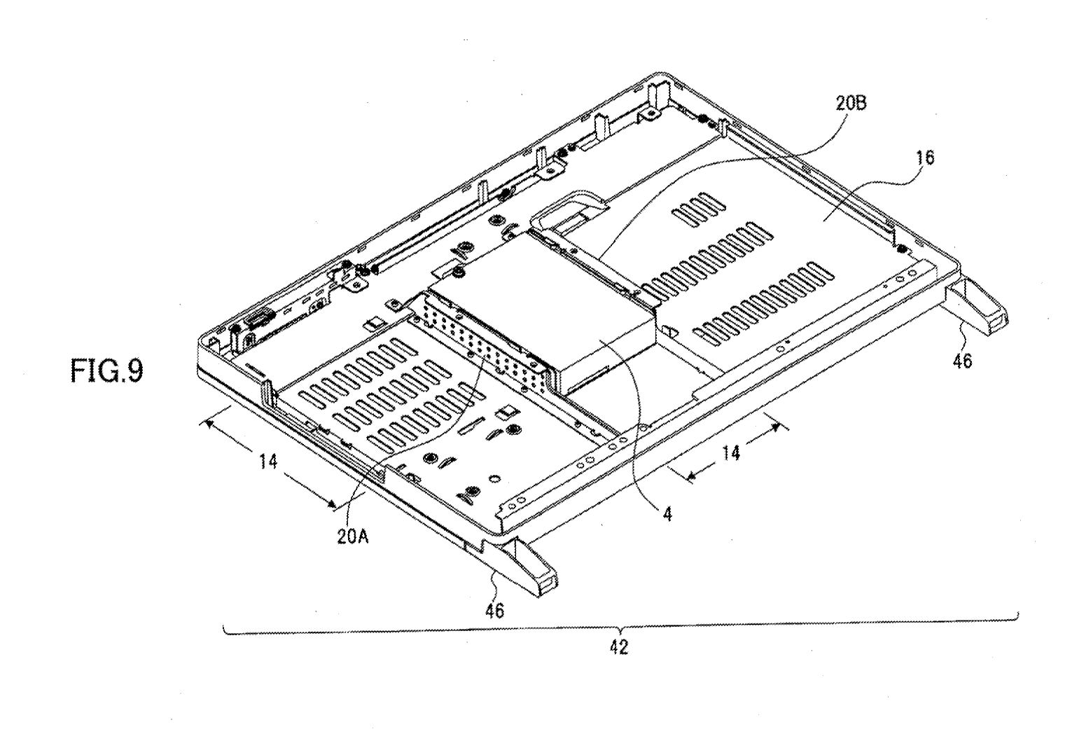

As illustrated in FIG. 6, the PC 42 includes a rear cover 52. The rear cover 52 is fixed to the housing 44 by plural fixing screws 54. A notch part 56 is formed in a central lower part of the rear cover 52. The rear stand 48 is formed in a manner protruding from the notch part 56. As illustrated in FIG. 9, the rear stand 48 is firmly fixed to the chassis 16 provided in the housing 44. The rear stand 48 being fixed to the chassis 16 and the rear cover 52 are separate components. Therefore, the rear cover 52 and the rear stand 48 can be separately detached from the housing 44.

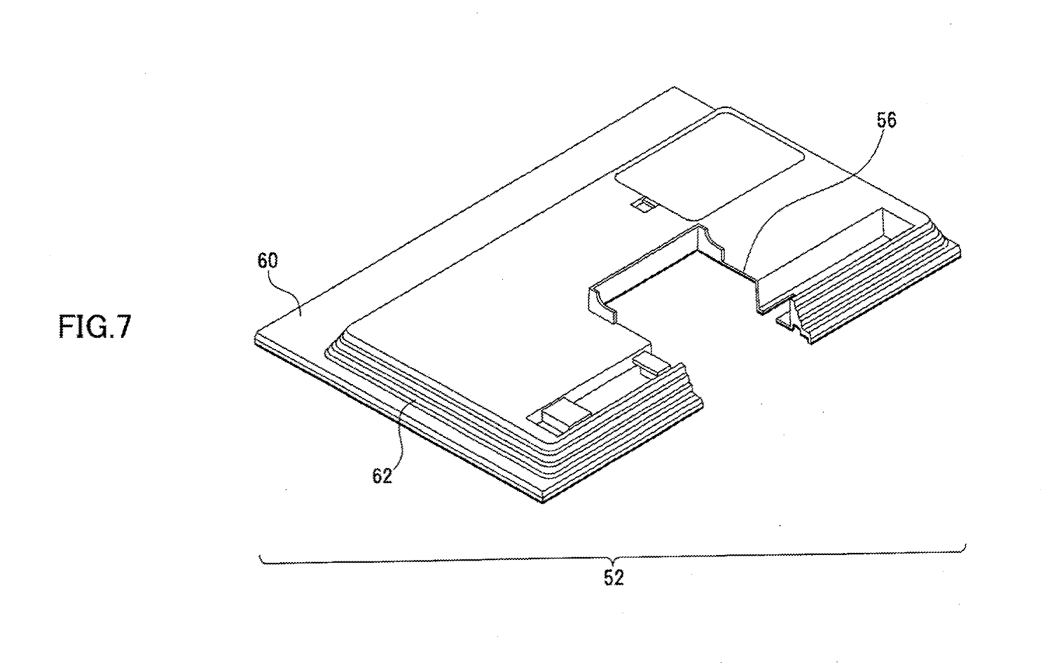

Next, the rear cover 52 according to an embodiment of the present invention is described with reference to FIG. 7. FIG. 7 is a rear perspective view of the rear cover 52 according to an embodiment of the present invention.

The rear cover 52 illustrated in FIG. 7 is a molded member formed of a synthetic resin. The rear cover 52 includes a cover body 60 to which the housing 44 is attached. The rear cover 52 includes a bulge part 62 protruding toward a rear side of the rear cover 52. The bulge part 62 is formed with steps, such that the bulge part 62 projects from the rear cover 52 toward the rear side step by step. The bulge part 62 is configured to serve as a reinforcement part that reinforces the rear cover 52 as well as a protection part that protects the below-described component(s) mounted on the chassis 16. The notch part 56 is formed from the center of the rear cover 52 toward a lower edge of the rear cover 52.

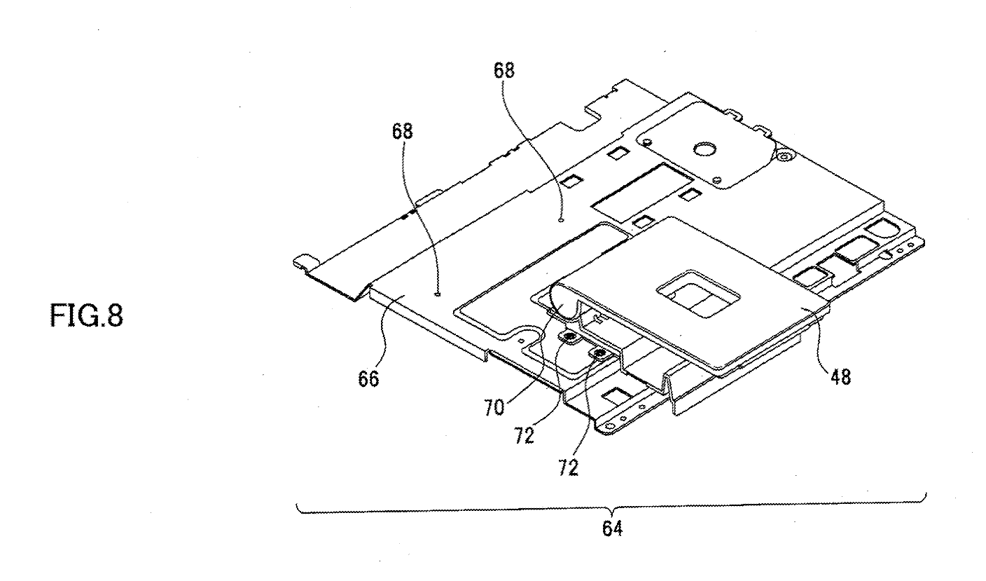

Next, the rear stand 48 being detached from the PC 42 is described with reference to FIG. 8. FIG. 8 is a perspective view illustrating the rear stand 48 in a state being detached from the chassis 16 according to an embodiment of the present invention.

The rear stand 48 illustrated in FIG. 8 is a molded member formed of a synthetic resin. As illustrated in FIG. 8, the rear stand 48 is attached to a stand support part 64. The stand support part 64 supports the rear stand 48. Further, the stand support part 64 is supported by the chassis 16. The stand support part 64 includes a stand chassis 66 which is to be fixed to the chassis 16 illustrated in FIG. 9. Similar to the chassis 16, the stand chassis 66 may be fabricated by performing a punching process on a metal plate. Plural insertion holes 68 are formed in the stand chassis 66 so that the stand chassis 66 can be fixed to the chassis 16 by inserting fixing screws into the insertion holes 68.

The rear stand 48 has a hinge part 70 that is to be fixed to the stand chassis 66 by plural fixing screws (not illustrated). The rear stand 48 can be adjusted to a desired angle where the hinge part 70 serves as a rotation center thereof. FIG. 8 illustrates a closed state of the rear stand 48.

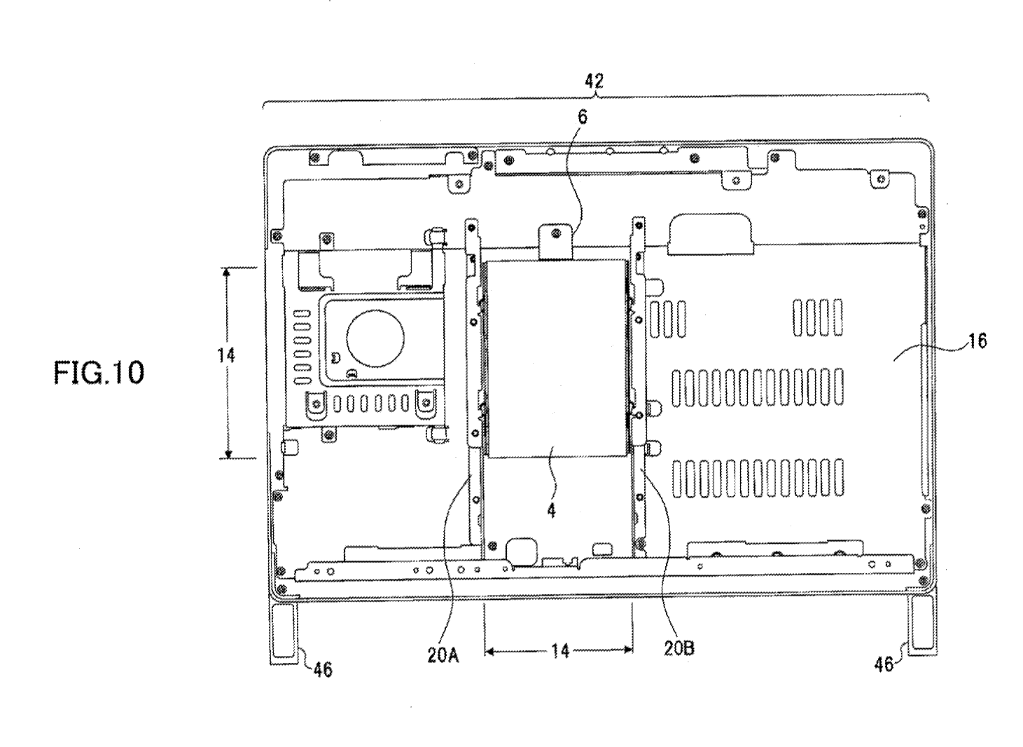

Next, an embodiment of the chassis 16 having the HDD unit 4 mounted thereon is described with reference to FIGS. 9 and 10. FIGS. 9 and 10 illustrate a part of the PC 42 in a state where the rear cover 52 and the stand support part 64 are detached from the PC 42.

The chassis 16 being fixed to the housing 44 includes the arrangement area 14 of the HDD unit 4. Further, the chassis 16 also includes the support panels 20A, 20B having the arrangement area 14 provided therebetween. The HDD unit 4 being fixed to the bracket 6 is provided in the space between the support panels 20A, 20B.

Each support panel 20A, 20B serves as a support or a fixing part of the bracket 6 that fixes the HDD unit 4. Additionally, each support panel 20A, 20B serves as a fixing part of the stand chassis 66.

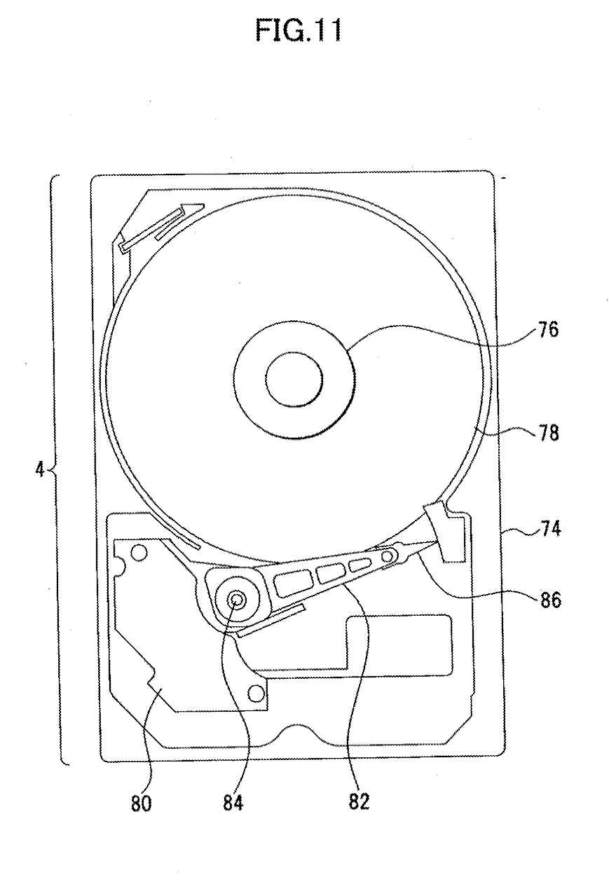

Next, the HDD unit 4 according to an embodiment of the present invention is described with reference to FIG. 11. FIG. 11 is a schematic diagram illustrating an example of the configuration of the HDD unit 4 according to an embodiment of the present invention.

As described above, the HDD unit 4 is an example of a device unit including a rotation mechanism. A housing 74 of the HDD unit 4 has a flat, rectangular parallelepiped shape. The rotation mechanism (in this embodiment, a spindle motor 76) of the HDD unit 4 is positioned on a center axis of the housing 74 relative to the longitudinal direction of the housing 74. A disk 78 is placed on a spindle of the spindle motor 76. The disk 78 is a recording medium that is rotated by the spindle motor 76. A swing arm 82 is provided in an area adjacent to the disk 78. The swing arm 82 is rotated by a voice coil motor 80. The swing arm 82 pivotally rotates around a rotation fulcrum 84. A cantilever 86, which is attached to a tip of the swing arm 82, is positioned at a recording track of the disk 78.

With the above-described configuration, the vibration due to the rotation (rotational vibration) of the spindle motor 76 is transmitted to the housing 74. The rotational vibration transmitted to the housing 74 is further transmitted to the bracket 6 that fixes the HDD unit 4 and to the part of the chassis 16 in the arrangement area 14

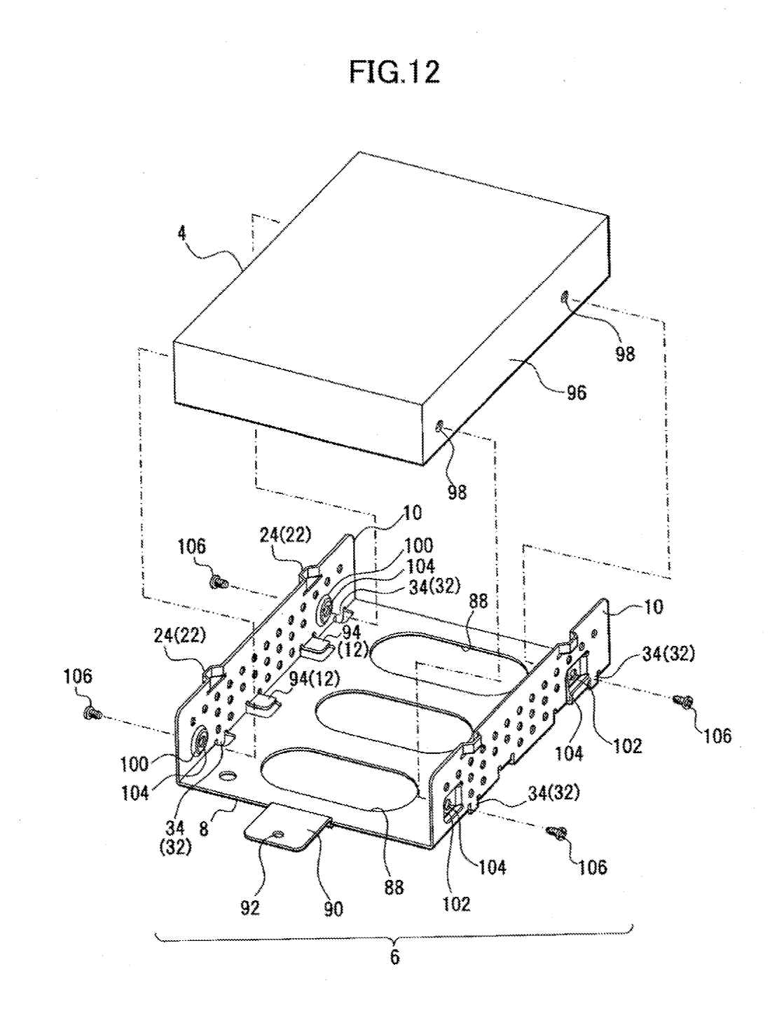

Next, an embodiment of the bracket 6 that fixes the HDD unit 4 is described with reference to FIG. 12. FIG. 12 is a perspective view illustrating an example of the HDD unit 4 and the bracket 6 according to an embodiment of the present invention.

The bracket 6 includes the bottom plate 8 and the side plates 10 perpendicularly intersecting respective edges of the bottom plate 8. The bottom plate 8 is shaped as a rectangle having an area that is slightly larger than that of the bottom surface of the HDD unit 4. Plural elliptical heat release holes 88 are formed in the bottom plate 8. By forming the heat release holes 88, the weight of the bottom plate 8 can be reduced. The bottom plate 8 includes a fixing part 90. The fixing part 90 is formed in a manner protruding from one edge in a longitudinal direction of the bottom plate 8. The fixing part 90 includes a through-hole 92 to which a fixing screw (not illustrated) is inserted.

Plural shelf parts 94 are formed in each side plate 10 by lancing the bottom plate 8. The shelf parts 94 are formed slightly higher than the bottom plate 8. The shelf parts 94 support the HDD unit 4 and define the height of the HDD unit 4 mounted on the bracket 6.

Plural fixing holes 98 are formed in sidewalls 96 of the HDD unit 4. Plural projection parts 100 are formed in the side plates 10 of the bracket 6 in correspondence with the fixing holes 98. The plural projection parts 100 project toward the sidewalls 96 that are to be fixed to the bracket 6. The side plates 10 have recess parts 102 formed on the opposite side of the projection parts 100. A through-hole 104 is formed in each of the projection parts 100. A fixing screw 106 is inserted in the through-hole 104. The fixing screw 106 penetrating the through-hole 104 is fixed to the corresponding fixing hole 98 of the HDD unit 4. Thereby, the HDD unit 4 is fixed to the bracket 6. In other words, the HDD unit 4 and the bracket 6 are combined to form a united body.

The protrusion parts 24 of the plural engagement mechanisms 22 are formed in the side plates 10 of the bracket 6. The protrusion parts 24 are formed by performing a press working process to two parts on the edge in a longitudinal direction of the side plate 10. Thereby, the protrusion parts 24 protrude toward the outer side of the bracket 6. Although two protrusion parts 24 are formed in the side plate 10 in this embodiment, one protrusion part 24 may be formed in the side plate 10 or three or more protrusion parts 24 may be formed in the side plate 10.

Further, the protrusion part 34 of the locking mechanism 32 is formed below the protrusion part 24 of the engagement mechanism 22 at the lower edge of the side plate 10. The protrusion part 34 is formed by press working and lancing the bottom plate 8, so that the protrusion part 34 protrudes downward from the bottom surface 8.

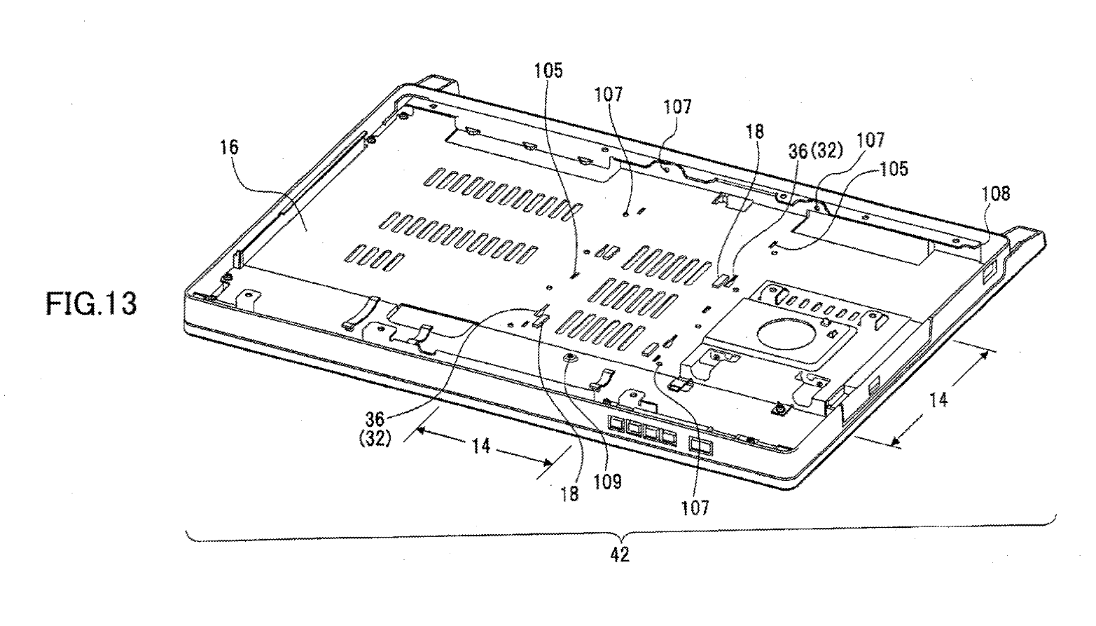

Next, an embodiment of the chassis 16 (prior to being fixed to the bracket 6) is described with reference to FIG. 13. FIG. 13 is a rear perspective view of a part of the PC 42 in a state where the rear cover 52, the stand support part 64, the HDD unit 4, and the bracket 6 are detached therefrom according to an embodiment of the present invention.

The chassis 16 includes the arrangement area 14 onto which the bracket 6 is to be installed. Plural gaskets are provided in the arrangement area 14 in correspondence with the bottom plate 8 of the bracket 6. In this embodiment, two gaskets 18 are provided in corresponding positions in a width direction of the plate 8 of the bracket 6, and two gaskets 18 are provided in corresponding positions in a length direction of the plate 8 of the bracket 6 (four positions). By allocating the plural gaskets 18 in the corresponding positions in the arrangement area 14, the bracket 6 can be arranged in a well-balanced position relative to the longitudinal and the transverse directions of the arrangement area 14.

The slits 36 of the locking mechanisms 32 for locking the bracket 6 to the chassis 16 are formed in the arrangement area 14. In this embodiment, two slits 36 are formed in corresponding positions in the width direction of the bottom plate 8 of the bracket 6 and two slits 36 are formed in corresponding positions in the length direction of the bottom plate 8 of the bracket 6 (four positions). By allocating the slits 36 in the corresponding positions, the bracket 6 can be locked in a well-balanced position relative to the longitudinal and the transverse directions of the arrangement area 14.

Plural locking holes 105 and screw holes 107 are formed in the chassis 16 for locking and fixing the support panels 20A, 20B having the arrangement area 14 provided therebetween. A vertical wall 108 is formed at an edge part of the chassis 16 by folding a portion of the chassis 16. The screw holes 107 are also formed in the vertical wall 108 for fixing the support panels 20A, 20B to the chassis 16.

Further, a screw hole 109 is formed in a predetermined position in the longitudinal direction of the through-hole 92 of the fixing part 90 of the bracket 6 for fixing the bracket 6 to the chassis 16.

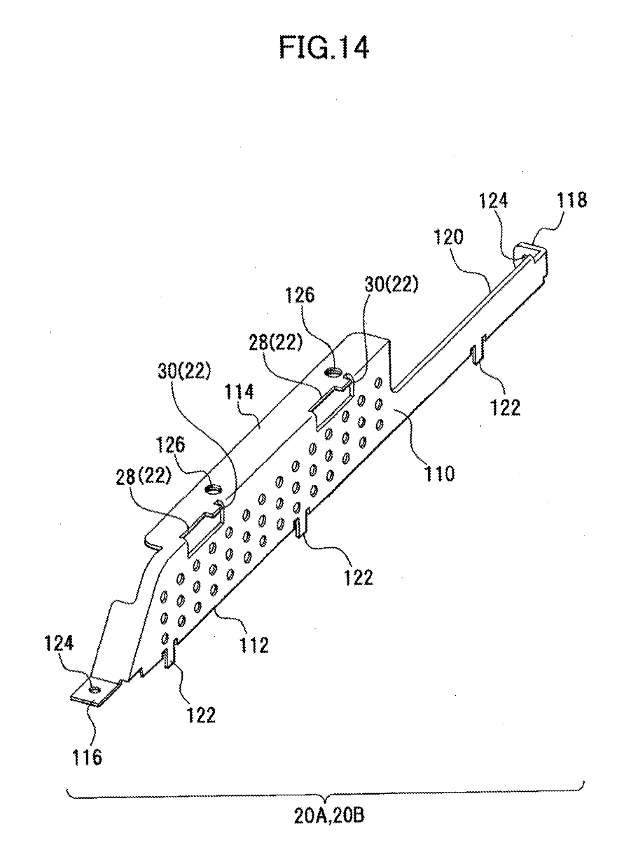

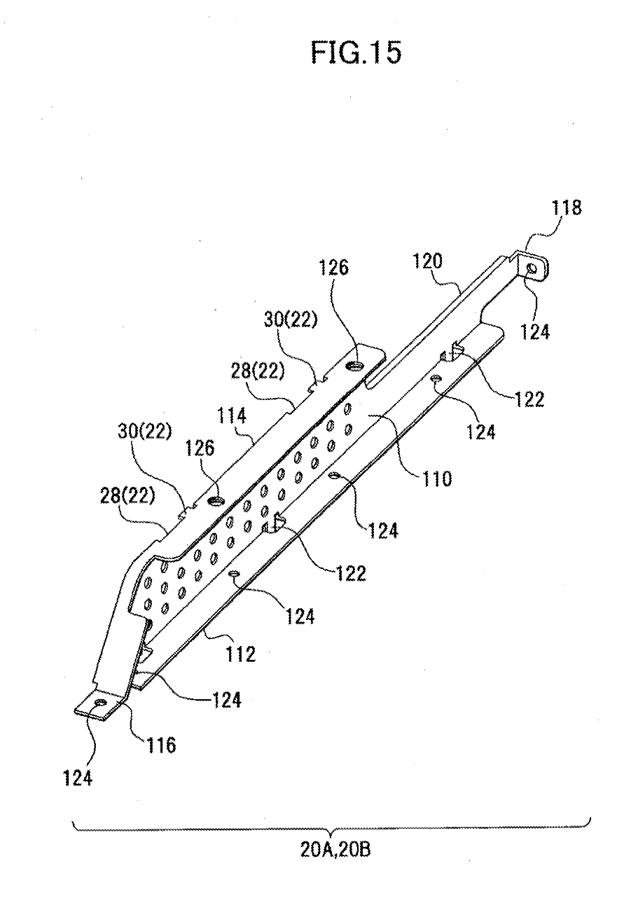

Next, an embodiment of the support panels 20A, 20B is described with reference to FIGS. 14 and 15. FIG. 14 is a perspective view of one of the support panels 20A, 20B when viewed from the arrangement area 14 according to an embodiment of the present invention. FIG. 15 is a perspective view of one of the support panels 20A, 20B when viewed from the outside of the arrangement area 14 according to an embodiment of the present invention. The support panel 20A and the support panel 20B are symmetrical. Each of the support panels 20A, 20B includes a vertical wall part 110, a lower fixing part 112, an upper fixing part 114, and side fixing parts 116, 118. The vertical wall part 110 includes a wall portion that perpendicularly intersects with the arrangement area 14 of the chassis 16 and extends to the side fixing part 118. The wall portion of the vertical wall part 110 is provided between the lower fixing part 112 and the upper fixing part 114 so that the lower fixing part 112 and the upper fixing part 114 are maintained parallel to each other. The vertical wall part 110 also includes a reinforcement portion 120 extending from the upper fixing part 114 to the side fixing part 118. The reinforcement portion 120 is formed by folding (e.g., a hemming process) a portion of the support panel 20A, 20B. Further, plural protrusion parts 122 are formed at a lower edge of the vertical wall part 110 by punching the lower fixing part 112. Each of the protrusion parts 122 is to be inserted to the corresponding locking hole 105 of the chassis 16.

A portion of the lower fixing part 112 is folded in an intersecting direction relative to the vertical wall part 110. Through-holes 124 are formed in the folded portion of the lower fixing part 112 in correspondence with the through-hole 107 of the chassis 16. Likewise, the through-holes 124 are also formed in each of the side fixing parts 116, 118 in correspondence with the through-holes 107 of the chassis 16.

The upper fixing part 114 is also folded in an intersecting direction relative to the vertical wall part 110. Together with the lower fixing part 112, the upper fixing part 114 serves to reinforce the vertical wall part 110. Screw holes 126 are formed in the upper fixing part 114 for fixing corresponding screws to the stand chassis 66.

In this embodiment, two window parts 28 of the engagement mechanisms 22 are formed at corresponding corner parts between the upper fixing part 114 and the vertical wall part 110. Further, the lock part 30 is formed in each of the window parts 28. The window parts 28 are formed having a predetermined interval therebetween. The lock part 30 is formed by punching a portion of the support panel 20A, 20B corresponding to the window part 28 and lancing the portion of the support panel 20A, 20B. Thereby, the lock part 30 protrudes toward the support panel 20A, 20B of the opposite side. In other words, the lock part 30 protrudes from the surface of the wall portion of the vertical wall part 110 toward the opposite side.

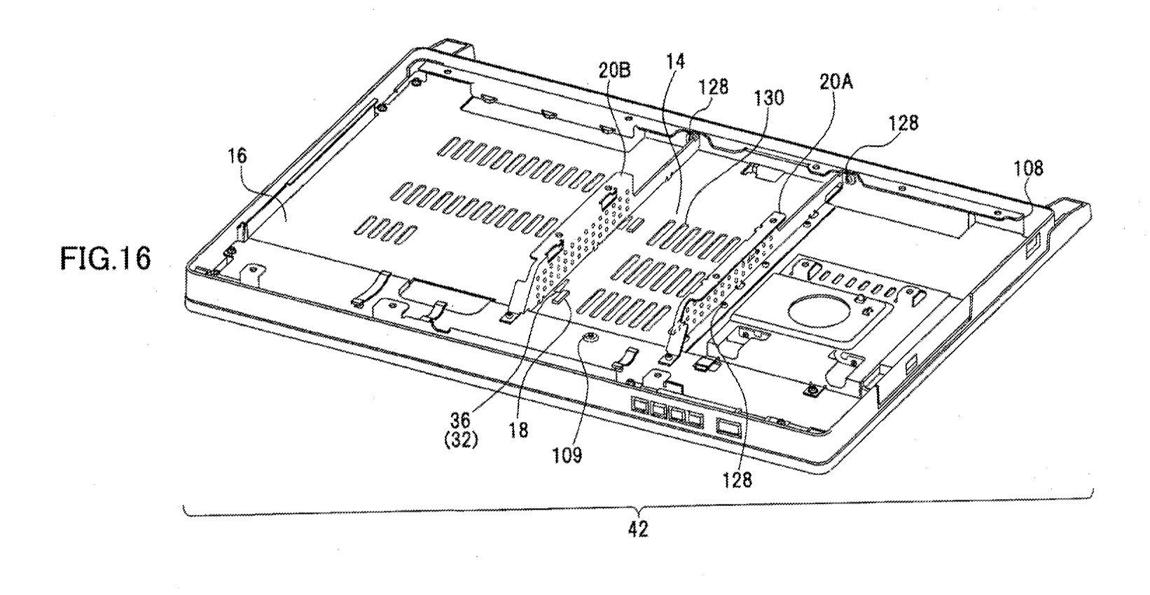

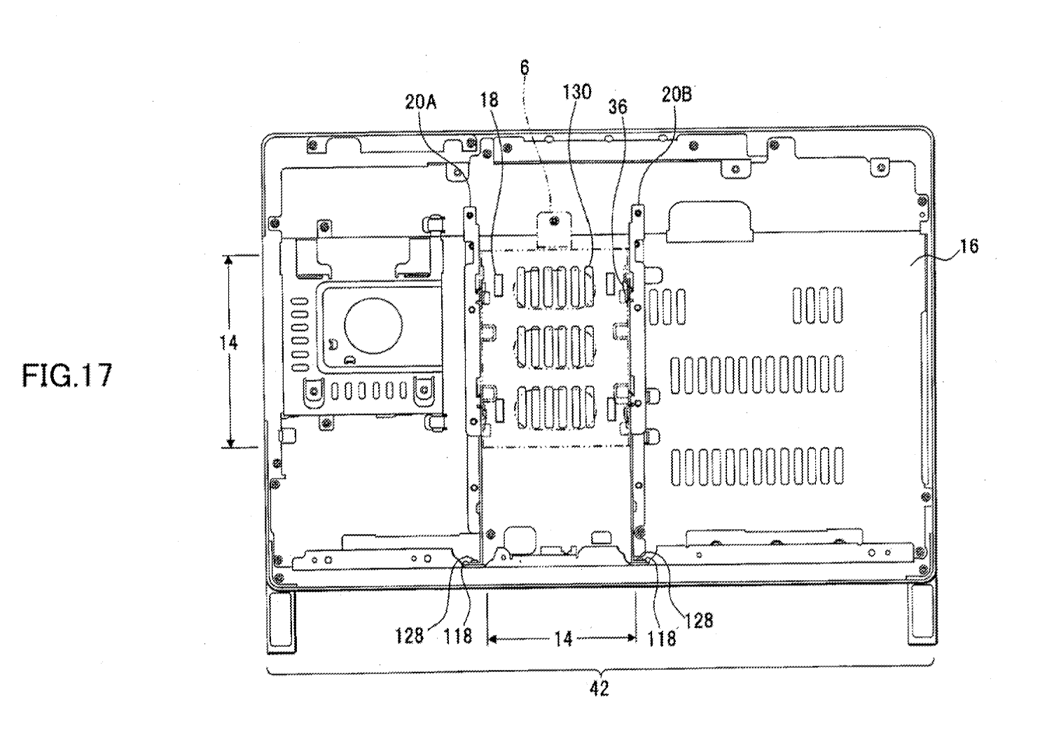

Next, an embodiment of an arrangement of the components (e.g., support panels 20A, 20B) fixed to the chassis 16 is described with reference to FIGS. 16 and 17. FIG. 16 is a perspective view illustrating the PC 42 viewed from the rear in a state where the support panels 20A, 20B are mounted on the chassis 16 according to an embodiment of the present invention. FIG. 17 is a rear view of the PC 42 in a state where the support panels 20A, 20B are mounted on the chassis 16 according to an embodiment of the present invention.

As illustrated in FIG. 16, the support panel 20A and the support panel 20B are arranged in parallel on the chassis 16 having the arrangement area 14 provided therebetween. The positions of the through-holes 107 of the chassis 16 (see FIG. 13) are matched with the positions of the through-holes 124 of the support panels 20A, 20B. The support panels 20A, 20B are firmly fixed to the chassis 16 by fastening with rivets 128 inserted in the through-holes 107, 124. Thereby, the support panels 20A, 20B are integrated with the chassis 16 to form a united body.

As illustrated in FIG. 17, the support panels 20A, 20B, being fixed to the chassis 16, are arranged having the arrangement area 14 provided therebetween. Plural vent holes 130 are formed in the arrangement area 14 for cooling the HDD unit 4 and reducing the weight of the chassis 16.

As illustrated in FIG. 17, the window parts 28 and the lock parts 30 of the engagement mechanisms 22 formed in the support panels 20A, 20B, the gaskets 18 arranged on the chassis 16, and the slits 36 of the locking mechanisms 32 formed in the chassis 16 are arranged along an edge part of the arrangement area 14 of the chassis 16. In other words, the bracket 6 is fixed to the chassis 16 in a manner that the bracket 6 engages the chassis 16 and the support panels 20A, 20B at the corners parts of the bracket 6 relative to the traverse and longitudinal directions of the bracket 6.

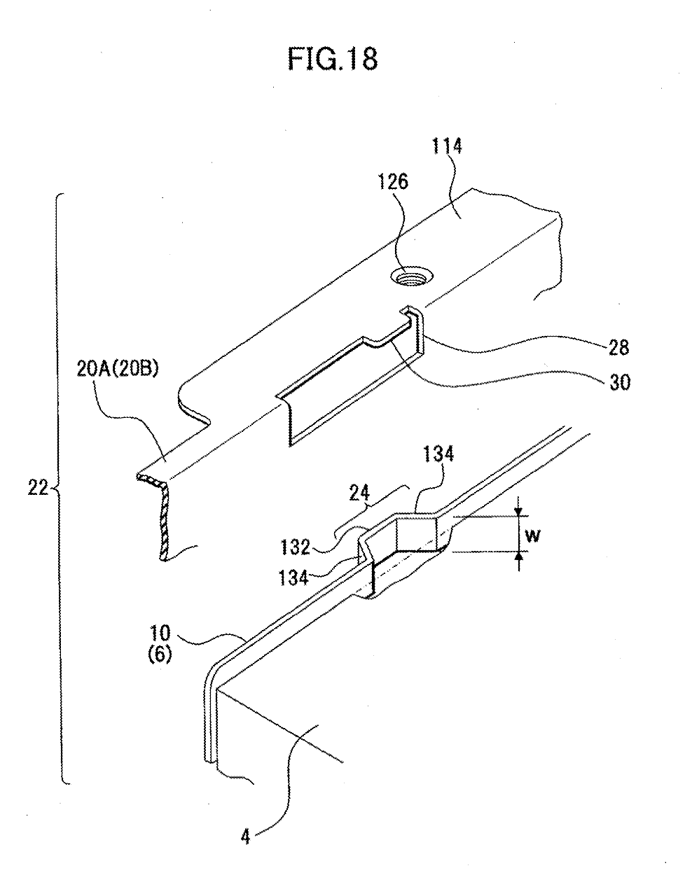

Next, an embodiment of the engagement mechanism 22 is described with reference to FIG. 18. FIG. 18 is an exploded view of the engagement mechanism 22 according to an embodiment of the present invention.

The engagement mechanism 22 is for engaging the bracket 6 and the support panels 20A, 20B. As illustrated in FIG. 18, the protrusion part 24 is formed in the side plate 10 of the bracket 6. The protrusion part 24 includes a peak portion 132 having a flat area and a pair of leg portions 134 that support the peak portion 132. The protrusion part 24 is reinforced by forming the peak portion 132 and the leg portions 134 with a predetermined width W.

The window part 28 is formed in the support panels 20A, 20B in correspondence with the protrusion part 24. The window part 28 is formed larger than the protrusion part 24 for allowing the protrusion part 24 to be inserted therein. The lock part 30 is formed at an upper edge of the window part 28 toward a position in which the bracket 6 is moved to a locking state. The lock part 30 is formed flush with the surface of the upper fixing part 114 relative to the height direction. The relationship of the height of the lock part 30 and the protrusion part 24 is set so that a recovering force can be exerted from the gaskets 18 maintained in a compressed state. For example, in a case where the bracket 6 is mounted where the gaskets 18 are not in a compressed state, the upper edge of the protrusion part 24 is set higher than the bottom surface of the lock part 30. Thereby, the protrusion part 24 can be locked to the lock part 30 when the protrusion part 24 is lowered by compressing the bracket 6.

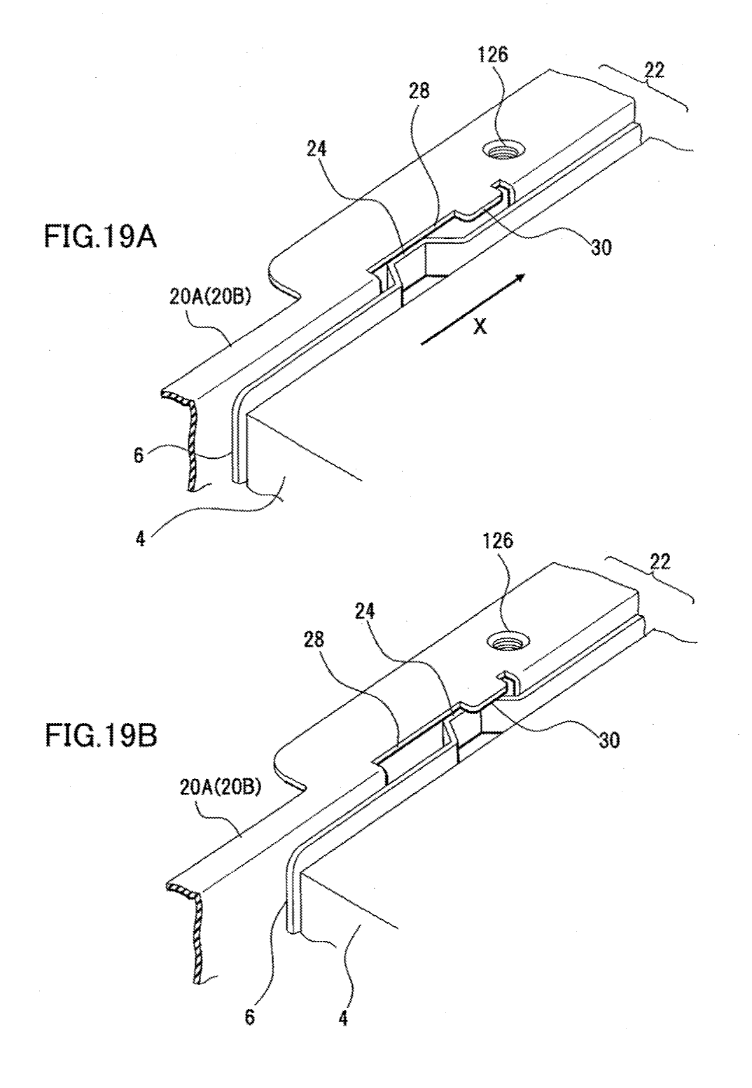

Next, an embodiment of the engaging relationship of the engagement mechanism 22 is described with reference to FIGS. 19A and 19B. FIG. 19A is a schematic diagram illustrating the engagement mechanism 22 before the bracket 6 and the support panels 20A, 20B are engaged according to an embodiment of the present invention. FIG. 19B is a schematic diagram illustrating the engagement mechanism 22 after the bracket 6 and the support panels 20A, 20B are engaged according to an embodiment of the present invention.

As illustrated in engagement mechanism 22 of FIG. 19A, the protrusion part 24 of the bracket 6 is inserted to the window part 28 of the support panel 20A, 20B. In this state, the protrusion part 24 in the window part 28 travels toward a lower surface of the lock part 30 by moving the bracket 6 in the direction X illustrated in FIG. 19A. As a result, the protrusion part 24 engages the lock part 30. Thereby, the bracket 6 engages the support panels 20A, 20B.

The traveling range of the protrusion part (i.e. the range in which the bracket 6 is moved to and fro direction X) is restricted by the window part 28. That is, the vertical edge of the window part 28 serves as a stopper for regulating the movement of the protrusion part 24.

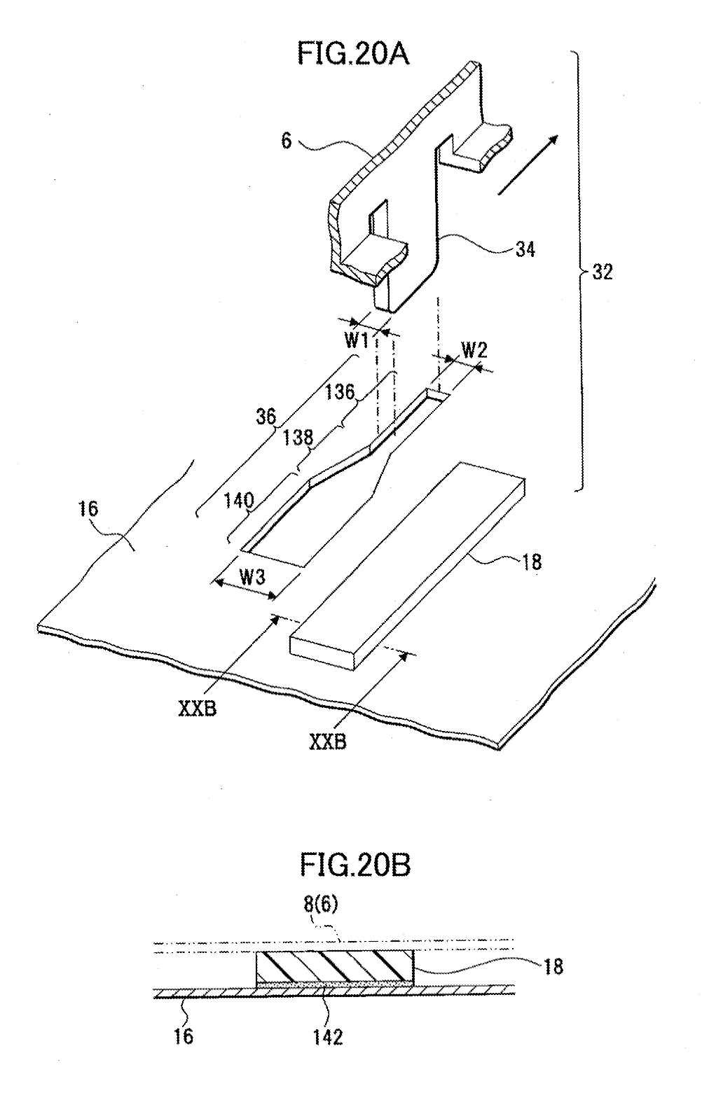

Next, an embodiment of the gasket 18 and the locking mechanism 32 is described with reference to FIGS. 20A and 20B.

As illustrated in FIG. 20A, the locking mechanism 32 of the bracket 6 and the chassis 16 is arranged in the vicinity of the gasket 18. The locking mechanism 32 includes the protrusion part 34 formed in the bracket 6 and the slit 36 formed in the chassis 16. The protrusion part 34 protrudes downward from a portion of the bracket 6. Taking the movement of the bracket 6, the slit 36 of the chassis 16 is formed into a shape that defines the position of the bracket 6. That is, the slit 36 has a shape that defines the position in which the movement of the bracket 6 terminates. The slit 36 includes a narrow recess portion 136, an inclination portion 138, and a wide recess portion 140. The narrow recess portion 136 has a width W₂ that is slightly greater than the thickness W1 of the protrusion part 34 (W2>W1). The wide recess portion 140 has a width W3 that is greater than the width W2 of the narrow recess portion 136 (W3>W2). The inclination portion 138 is a part where the shape of the wide recess portion 140 makes a gradual transition toward the shape of the narrow recess portion 136, vice versa. Because the protrusion part 34 is formed protruding downward in a state where the protrusion part 34 is inserted to the slit 36, the bracket 6 placed on the gaskets 18 can be moved in a vertical direction (up and down).

As illustrated in FIG. 20B, the gasket 18 may be fixed to the chassis 16 by an adhesive double-side coated sheet 142. Accordingly, the bottom plate 8 of the bracket 6 is placed on an upper surface of the gasket 18.

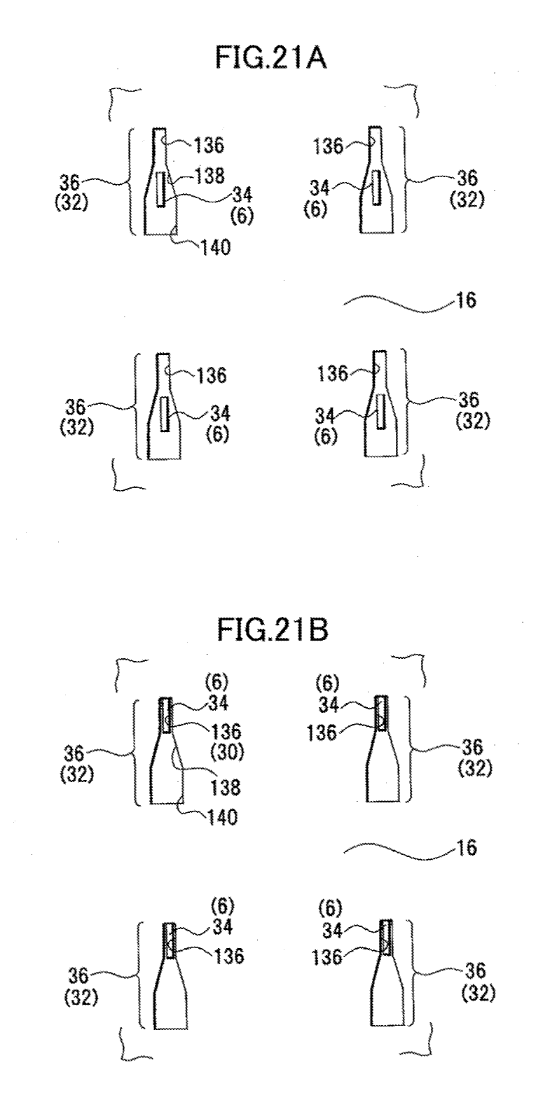

Next, an embodiment of the locking mechanism 32 in a state where the bracket 6 is placed on the gasket 18 is described with reference to FIGS. 21A and 21B. FIG. 21A is a schematic diagram illustrating the locking mechanism 32 before the bracket 6 and the chassis 16 are engaged according to an embodiment of the present invention. FIG. 21B is a schematic diagram illustrating the locking mechanism 32 after the bracket 6 and the chassis 16 are engaged according to an embodiment of the present invention.

As illustrated in FIG. 21A, in the four locking mechanisms 32 formed in the arrangement area 14 of the chassis 16 and corresponding parts of the bracket 6, the protrusion parts 34 are inserted into the wide recess portion 140 of corresponding slits 36. In the inserted state, the protrusion part 34 is guided along the inclination portion 138 and moved toward the narrow recess portion 136 by moving the bracket in the direction of the narrow recess portion 136. The position of the protrusion part 34 can be defined by the narrow recess portion 136. Thereby, the bracket 6 can be arranged in a predetermined position in the arrangement area 14.

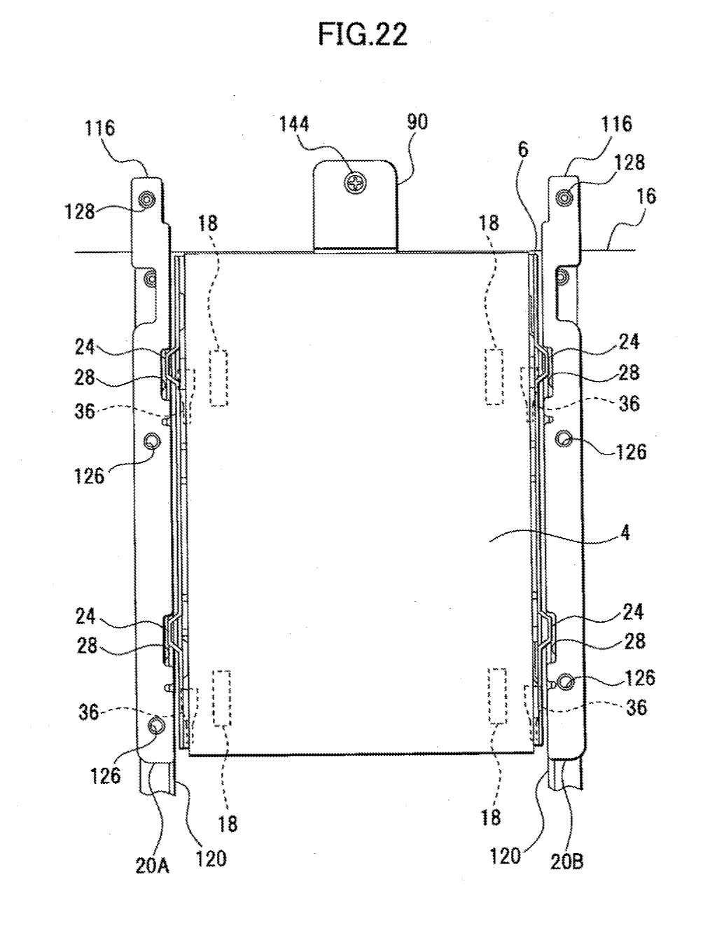

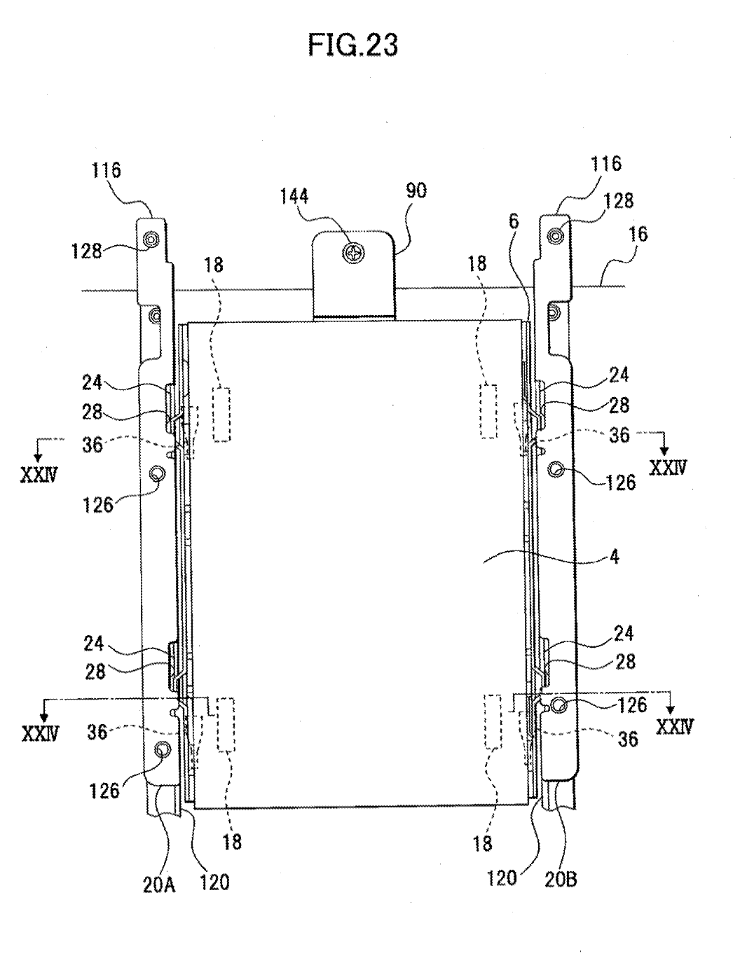

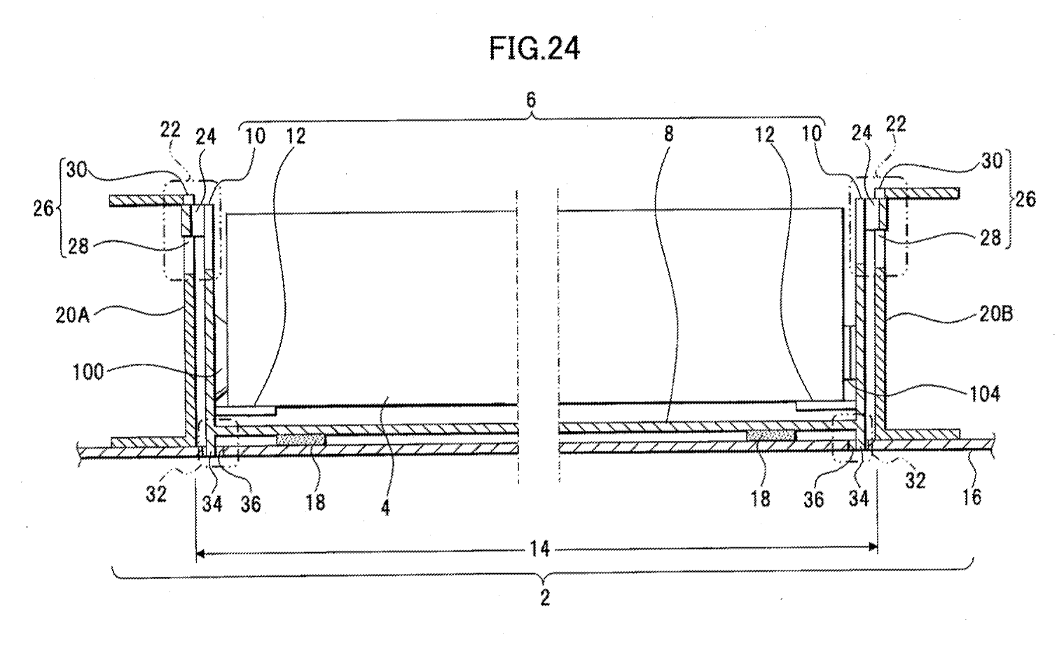

Next, an embodiment of the engagement of the bracket 6 and the support panels 20A, 20B is described with reference to FIGS. 22, 23, and 24. FIG. 22 is a schematic diagram illustrating a state before the bracket 6 and the support panels 20A, 20B are engaged according to an embodiment of the present invention. FIG. 23 is a schematic diagram illustrating a state after the bracket 6 and the support panels 20A, 20B are engaged (i.e. engaged state) according to an embodiment of the present invention. FIG. 24 is a cross-sectional view of the engaged state taken along line XXIV-XXIV of FIG. 23.

In a state where the protrusion parts 24 of the bracket 6 are inserted in the wide recess portions 140 of corresponding slits 36, the protrusion parts 24 of the bracket 6 are in a state inserted in the window parts 28 of the support panels 20A, 20B as illustrated in FIG. 22.

The bracket 6 keeps the gaskets 18 in a compressed state by exerting a pressing force P in the compression direction of the gasket 18 (i.e. direction for compressing the gasket 18) as illustrated by the arrow in FIG. 4. In this state, the bracket 6 is moved in the arrow direction X of FIG. 19A. Thereby, the protrusion part 24 of the bracket 6 travels toward a lower surface of the lock part 30. As a result, the protrusion part 24 engages the lock part 30. When the pressing force P is released in this engaged state, the recovering force of the gasket 18 is applied between each of the protrusion parts 24 of the bracket 24 and the corresponding lock parts 30 of the support panels 20A, 20B. Thereby, the engaging strength between the bracket 6 and the support panels 20A, 20B can be increased.

In this state, the position of the through-hole 92 of the fixing part 90 of the bracket 6 is matched with the position of the screw hole 107 of the chassis 16. Then, the chassis 16 is fixed to the bracket 6 by fastening a fixing screw 144 to the through-hole 92 and the screw hole 107.

As illustrated in FIG. 24, the engaging force generated by the engagement mechanisms 22, the locking force generated by the locking mechanisms 32, and the recovering force generated by the gaskets 18 enables the bracket 6 to be fixed to the chassis 16 in a predetermined position in the arrangement area 14 of the chassis 16 and maintain an engaged state with the chassis 16 by receiving the recovering force resulting from the resiliency of the gaskets 18.

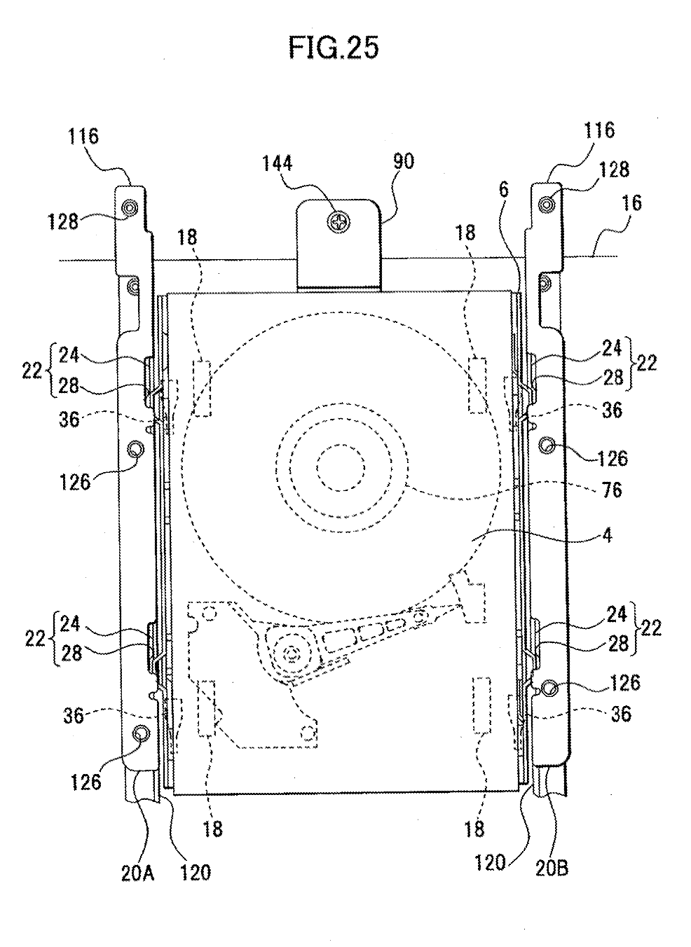

Next, an embodiment of the relationship between the gaskets 18, the engagement mechanisms 22, the fixing parts 90, the rotation mechanism of the HDD unit 4 mounted on the bracket 6 is described with reference to FIG. 25. FIG. 25 is a schematic diagram illustrating a positional relationship of the rotation mechanism of the HDD unit 4, the engagement mechanisms 22, and the locking mechanisms 32 according to an embodiment of the present invention.

The HDD unit 4 mounted on the bracket 6 is arranged in the arrangement area 14 located between the support panels 20A, 20B. The spindle motor 76 of the HDD unit 4 is mounted in the vicinity of a center portion of the arrangement area 14. Accordingly, the spindle motor 76 is positioned within a support area defined by four gaskets 18 and surrounded by the engagement mechanisms 22 provided at the four corners of the support area. In addition, the bracket 6 is fixed to the chassis 16 by the fixing screw 144 fastened to the fixing part 90 on the center axis of the spindle motor 76.

By fixing and engaging the bracket 6 and the chassis 16 in such manner, the bracket 6 can be firmly fixed to the chassis 16. In addition, the bracket 6 is positioned in the arrangement area 4 at which vibration can be absorbed by the gaskets 18. Because the chassis 16 and the bracket 6 are closely positioned to each other via the gaskets 18, the vibration generated by the rotation of the spindle motor 76 can be absorbed by the gaskets 18. As a result, the discomforting noise due to the vibration can be prevented.

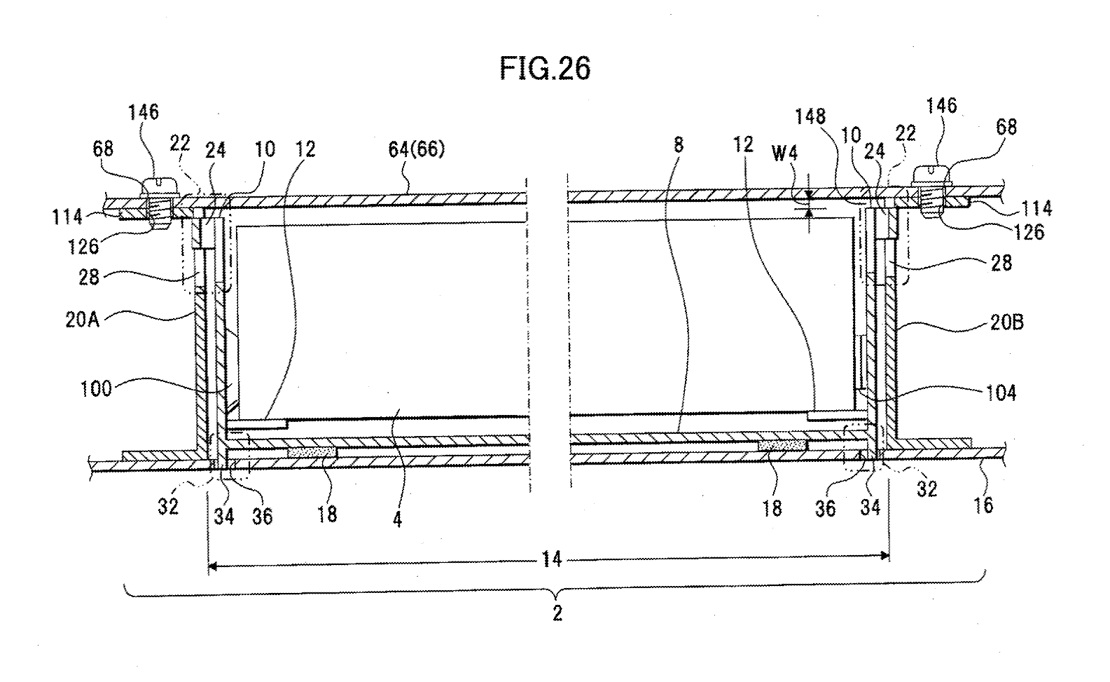

Next, an embodiment of attaching the support panels 20A, 20B and the stand chassis 66 is described with reference to FIG. 26. FIG. 26 is a cross-sectional view illustrating a housing structure having the stand chassis 66 attached to the support panels 20A, 20B according to an embodiment of the present invention.

As illustrated in FIG. 26, fixing screws 146, which are inserted into the insertion holes 68 of the stand chassis 66 of the stand support part 64, are fastened to corresponding screw holes 126 of the upper fixing part 114 of the support panels 20A, 20B fixed to the chassis 16. In other words, each upper fixing part 114 of the support panels 20A, 20B is bridged by the stand chassis 66 of the stand support part 64. As a result, the chassis 16 and the stand chassis 66 constitute a rigid housing structure having the support panels 20A, 20B provided therebetween. As illustrated in FIG. 26, the housing structure has a cylindrical cross-section.

Inside this housing structure, the bracket 6 having the HDD unit 4 mounted thereon is fixed to the support panel 20A, 20B, and the chassis 16 and protected by the housing structure. Accordingly, the HDD unit 4 can be protected by the rigid housing structure and resiliently supported by the gaskets 18.

The support panels 20A, 20B are formed having a height greater than the height of the side plates 10 of the bracket 6 including the protrusion parts 34. A space 148 is provided between a top surface of the side plate 10 and an attachment surface of the stand chassis 66. The space 148 has a width of W4 relative to the height direction. By providing this space 148, the engagement provided by the engagement mechanisms 22 and the locking force provided by the locking mechanisms 32 can be released when the fixing screw 146 is detached (unfastened). In other words, the bracket 6 can be attached and detached with respect to the chassis 16 by removing the stand chassis 66. By detaching the bracket 6, the HDD unit 4 can be detached from the bracket 6 in a case of repairing or replacing the HDD unit 4.

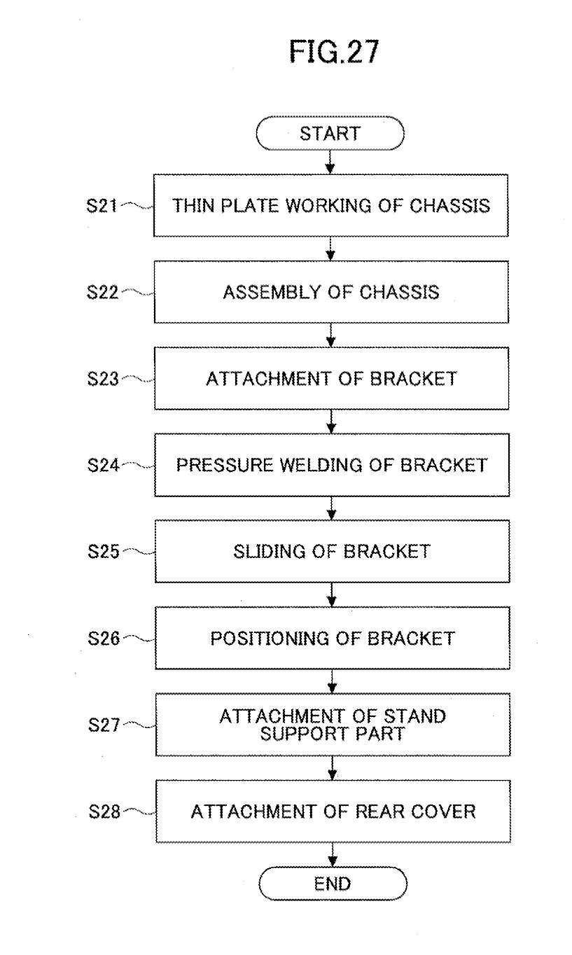

Next, an embodiment of the procedures for assembling the PC 42 is described with reference to FIG. 27. FIG. 27 is a flowchart illustrating the procedures for assembling the PC 42 according to an embodiment of the present invention. Prior to being assembled, the chassis 16 is formed by thin-plate-working (Step S21). Then, assembly of the chassis 16 is performed (Step S22). In the assembly, the gaskets 18 are arranged predetermined positions in the arrangement area 14 of the chassis 16. Further, the support panels 20A, 20B are attached to the chassis 16. Then, attachment of the bracket 6 is performed (Step S23). In other words, the protrusion parts 34 formed in the bottom plate 8 of the bracket 6 are inserted to corresponding slits 36 formed in the chassis 16 and the bracket 6 is placed on the gaskets 18. In this state, the gaskets 18 are compressed by the pressing force applied from the bracket 6 (Step S24). While the compressed state is being maintained, the bracket 6 is slid (moved) in a predetermined direction (Step S25). Thereby, the bracket 6 is positioned in a predetermined position and fixed to the predetermined position by locking the protrusion parts 24 of the engagement mechanisms 22 and the lock parts 30 of the support panels 20A, 20B (Step S26). In this case, the bracket 6 is fixed to the chassis 16 by fastening the fixing screw 144 to the fixing part 90 of the bracket 6.

After fixing the bracket 6 to the chassis 16, the stand support part 34 is attached to the upper fixing parts 114 of the support panels 20A, 20B (Step S27). Then, the rear cover 52 is attached to the housing 44 (Step S28).

With the above-described second embodiment, the following effects can be attained.

For example, the bracket 6 and the chassis 16 can firmly engage to each other without forming any space and prevent noise from being generated owing to engaging strength of the engagement mechanisms 22 along with the recovering force of the gaskets 18 maintained in a compressed state.

Further, the engagement process can be performed easily and the assembly process of the PC 42 can be performed efficiently owing to the engagement mechanism 22 (which engages the bracket 6 and the support panels 20A, 20B having the arrangement area 14 of the HDD unit 4 provided therebetween) positioned on the side of the HDD unit 4.

Further, the engaging strength between the bracket 6 and the chassis 16 can be increased by maintaining the gaskets 18 (arranged between the chassis 16 and the bracket 6 having the HDD unit 4 mounted thereon) in a compressed state and utilizing the engaging strength of the engagement mechanisms 22 along with the recovering force of the gaskets 18 maintained in the compressed state.

Further, the bracket 6 along with the HDD unit 4 can be attached and detached by detaching the stand chassis 66 from the chassis 16 without having to detach the stand support part 64.

### Other Embodiments

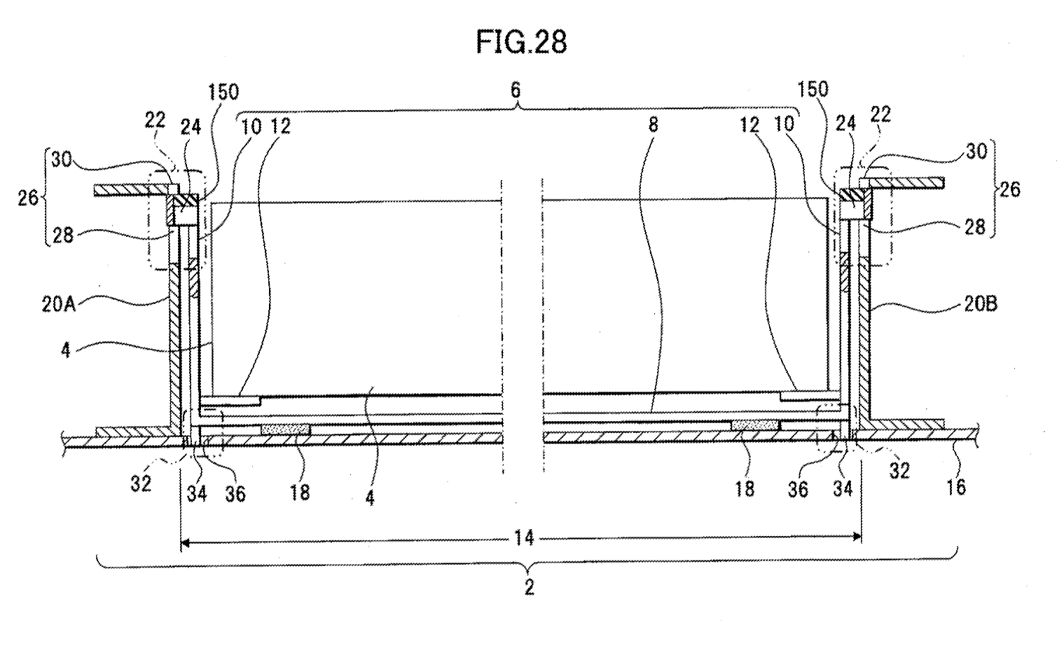

Although the protrusion part 24 and the lock part 30 of the engagement mechanism 22 are configured to directly contact each other according to the above-described embodiment of the present invention, a vibration proof member 150 may be provided between the protrusion part 24 and the lock part 30 according to a modified example of the engagement mechanism 22 as illustrated in FIG. 28. With the configuration illustrated in FIG. 28, both the gaskets 18 and the vibration proof member 150 can resiliently retain the bracket 6 and prevent a space from being generated.

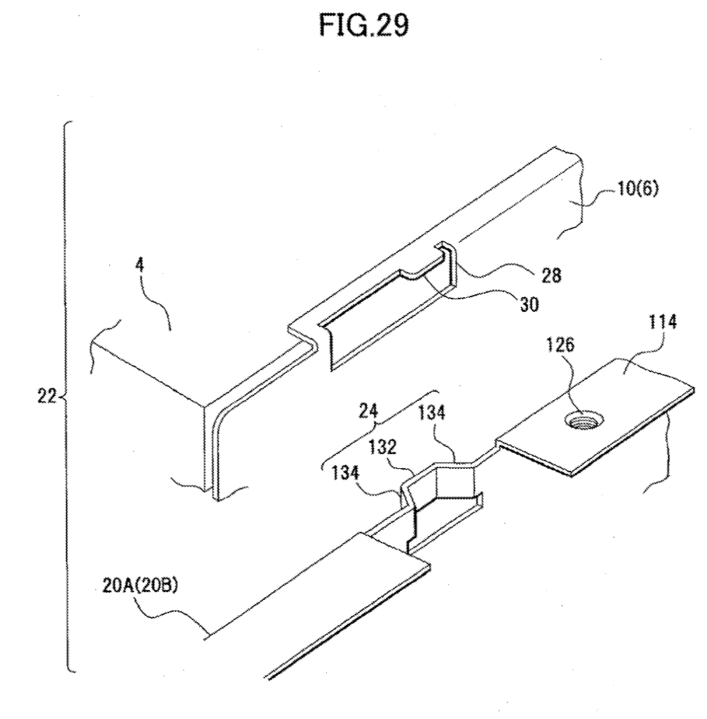

Although the engagement mechanism 22 has the protrusion part 24 formed in the bracket 6 and the lock part 30 formed in each of the support panels 20A, 20B according to the above-described embodiment of the present invention, the engagement mechanism 22 is not limited to such configuration. For example, as illustrated in FIG. 29, the engagement mechanism 22 according to a modified example may have the protrusion part 24 formed in each of the support panels 20A, 20B and the lock part 30 formed in the bracket 6.

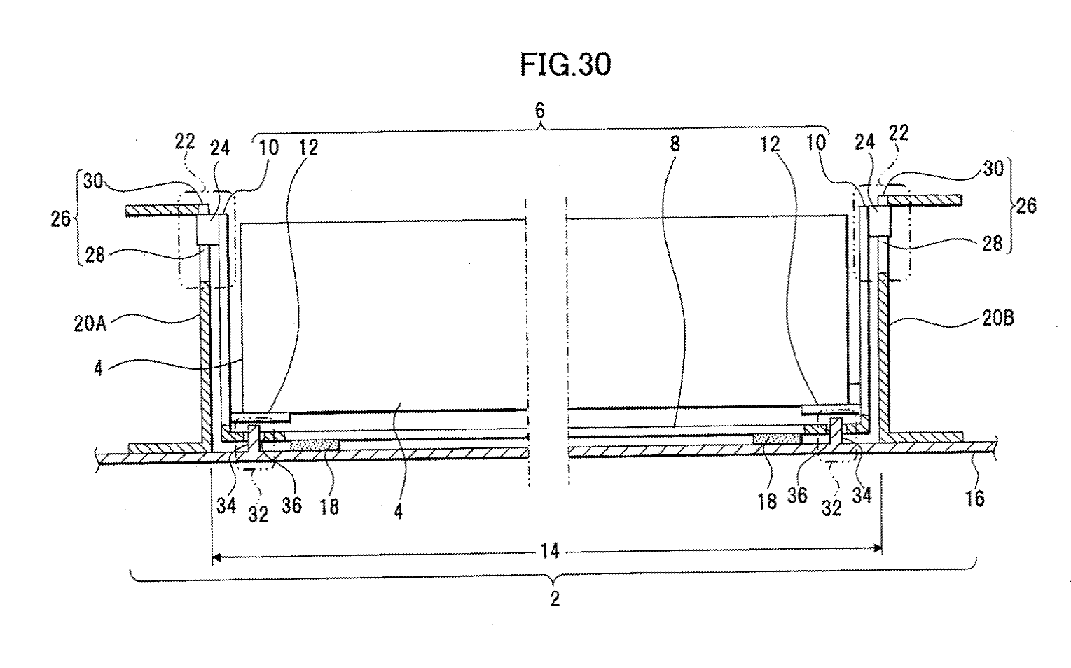

Although the locking mechanism 32 has the protrusion part 34 formed in the bottom plate 8 of the bracket 6 and the slit 36 formed in the chassis 16 according to the above-described embodiment of the present invention, the locking mechanism 32 is not limited to such configuration. For example, as illustrated in FIG. 30, the locking mechanism 30 according to a modified example may have the slit 36 formed in the bottom plate 8 of the bracket 6 and the protrusion part 34 formed in the chassis 16 according to a modified example.

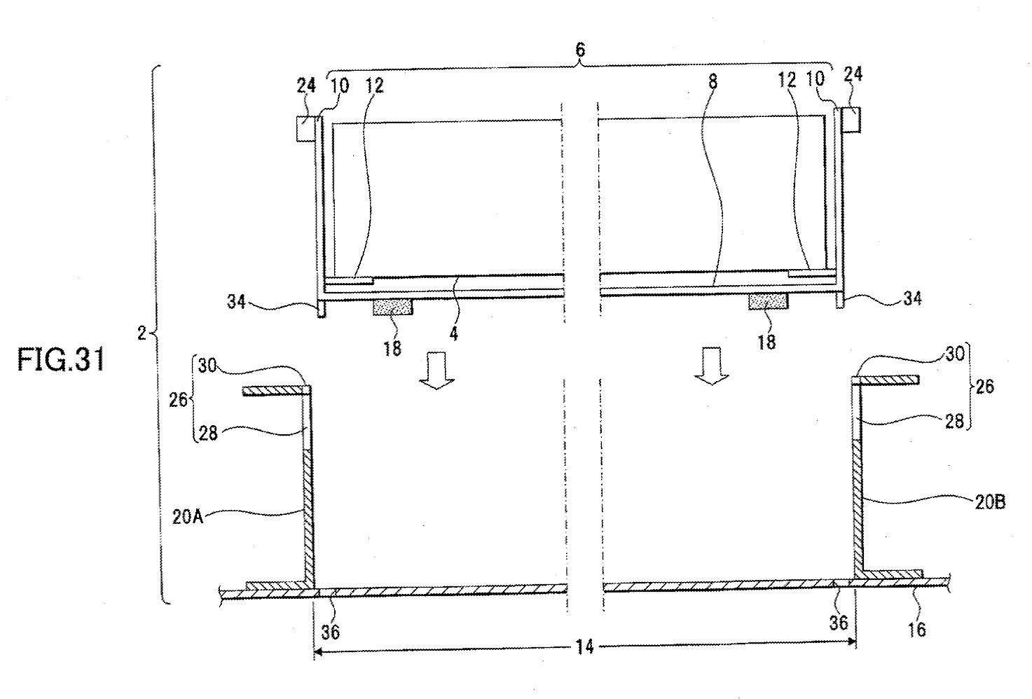

Although the gaskets 18 are included in the chassis 16 according to the above-described embodiment of the present invention, the gaskets 18 are not limited to such configuration. For example, the gaskets 18 may be included in the bracket 6 as illustrated in FIG. 31, so that the gaskets 18 are sandwiched (interposed) between the bracket 6 and the chassis 16.

Although the PC 42 is an example of the electronic device including a HDD unit, the above-described embodiments may be applied to other electronic devices. For example, a television set, an electronic game device, or a projector may be used as the electronic device or manufactured as the electronic device according to a modified example.

Although the stand chassis 66 is in a detached state in a case of attaching or detaching the bracket 6 to or from the chassis 16 according to the above-described embodiment, other configurations may be applied. For example, by forming a window part in the stand chassis 66 for allowing the bracket 6 to be inserted, the bracket 6 can be attached or detached without having to detach the stand chassis 66.

Although the support panels 20A, 20B are fixed to the chassis 16 by the rivets 128 according to the above-described embodiment, the support panels 20A, 20B may be fixed to the chassis 16 by a fixing member other than the rivets 128 (e.g., fixing screws) or by welding.

With the above-described embodiments of the present invention, the bracket and the chassis can firmly engage to each other without forming any space and prevent noise from being generated owing to engaging strength of the engagement mechanisms along with the recovering force of the vibration absorbing members maintained in a compressed state.

With the above-described embodiments of the present invention, the engagement process can be performed easily and assembly of the electronic device can be performed efficiently owing to the engagement mechanism (which engages the bracket and the support panels having the device arrangement area provided therebetween) positioned on the side of the device unit.

With the above-described embodiments of the present invention, the engaging strength between the bracket and the chassis can be increased by maintaining the vibration absorbing members (arranged between the chassis and the bracket having the device unit mounted thereon) in a compressed state and utilizing the engaging strength of the engagement mechanisms along with the recovering force of the vibration absorbing members maintained in the compressed state.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a device unit including a rotation mechanism;
a bracket on which the device unit is mounted;
a chassis including an arrangement area onto which the bracket is installed, a plurality of vibration absorbing members provided in the arrangement area, and first and second support panels having the arrangement area provided therebetween;
a first engagement mechanism provided between the first support panel and the bracket; and
a second engagement mechanism provided between the second support panel and the bracket;
wherein the first and the second engagement mechanisms are configured to engage the chassis and the bracket by compressing the plural vibration absorbing members between the chassis and the bracket.

2. The electronic device as claimed in claim 1, further comprising:
a locking mechanism configured to lock the bracket to the chassis where the chassis and the bracket are in a position engaged by the first and the second engagement mechanisms.

3. The electronic device as claimed in claim 1,
wherein the first engagement mechanism includes
a first protrusion part formed in the bracket, and
a first engagement part formed in the first support panel and configured to engage with the first protrusion part;
wherein the second engagement mechanism includes
a second protrusion part formed in the bracket, and
a second engagement part formed in the second support panel and configured to engage to the second protrusion part.

4. The electronic device as claimed in claim 1,
wherein the first engagement mechanism includes
a first protrusion part formed in the first support panel, and
a first engagement part formed in the bracket and configured to engage with the first protrusion part;
wherein the second engagement mechanism includes
a second protrusion part formed in the second support panel, and
a second engagement part formed in the bracket and configured to engage with the second protrusion part.

5. The electronic device as claimed in claim 2,
wherein the locking mechanism includes
a protrusion part formed in the bracket and
a recess part formed in the chassis and configured to insert the protrusion part thereto.

6. The electronic device as claimed in claim 2,
wherein the locking mechanism includes
a protrusion part formed in the chassis and
a recess part formed in the bracket and configured to insert the protrusion part thereto.

7. The electronic device as claimed in claim 1, wherein a rotation center of the rotation mechanism is surrounded by the plural vibration absorbing members provided on the chassis.

8. The electronic device as claimed in claim 3,
wherein the first support panel includes a first window part formed in the first engagement part,
wherein the first engagement part and the first protrusion part are configured to engage by inserting the first protrusion part into the first window part and sliding the bracket,
wherein the second support panel includes a second window part formed in the second engagement part,
wherein the second engagement part and the second protrusion part are configured to engage by inserting the second protrusion part into the second window part and sliding the bracket.

9. The electronic device as claimed in claim 4,
wherein the bracket includes a first window part formed in the first engagement part,
wherein the first engagement part and the first protrusion part are configured to engage by inserting the first protrusion part into the first window part and sliding the bracket,
wherein the bracket includes a second window part formed in the second engagement part,
wherein the second engagement part and the second protrusion part are configured to engage by inserting the second protrusion part into the second window part and sliding the bracket.

10. A method for manufacturing an electronic device, the method comprising:
attaching a device unit including a rotation mechanism to a bracket;
forming a chassis including an arrangement area onto which the bracket is installed, a plurality of vibration absorbing members provided in the arrangement area, and first and second support panels having the arrangement area provided therebetween;
compressing the plural vibration absorbing members between the chassis and the bracket; and
engaging the chassis and the bracket with a first engagement mechanism provided between the first support panel and the bracket and a second engagement mechanism provided between the second support panel and the bracket.

11. The method as claimed in claim 10, further comprising:
locking the bracket to the chassis where the chassis and the bracket are in a position engaged by the first and the second engagement mechanisms.
